(19) United States
(12) Patent Application Publication
(10) Pub. No.: US 2017/0288162 A1
(43) Pub. Date: Oct. 5, 2017

(54) ORGANIC EL ELEMENT

(71) Applicants: JOLED INC., Tokyo (JP); JAPAN DISPLAY INC., Tokyo (JP)

(72) Inventors: Toshiyuki AKIYAMA, Tokyo (JP); Kosuke MISHIMA, Tokyo (JP); Takahiro KOMATSU, Tokyo (JP)

(73) Assignees: JOLED INC., Tokyo (JP); JAPAN DISPLAY INC., Tokyo (JP)

(21) Appl. No.: 15/472,427

(22) Filed: Mar. 29, 2017

(30) Foreign Application Priority Data
Mar. 30, 2016 (JP) 2016-068481

(51) Int. Cl. H01L 51/50; H01L 51/52

(52) U.S. Cl. CPC H01L 51/5004; H01L 51/5206; H01L 51/5056; H01L 51/5012; H01L 51/5072; H01L 51/5221; H01L 2251/552

(57) ABSTRACT

ΔE1 denoting difference between LUMO energy level of hole transport and LUMO energy level of light-emitting layer, μe1 denoting electron mobility of the hole transport layer, and μe2 denoting electron mobility of the light-emitting layer satisfy

$$\frac{μ e 1}{μ e 2} \times exp ( - Δ E 1 \times 38.681731 ) \leq 2.090 \times {10}^{- 2}$$

$$when μ e 1 < μ e 2 , and satisfy$$

$$exp ( - Δ E 1 \times 38.681731 ) \leq 2.090 \times {10}^{- 2}$$

$$when μ e 1 \geq μ e 2 ,$$

ΔE2 denoting difference between LUMO energy level of light-emitting layer and LUMO energy level of electron transport layer, μe2 denoting electron mobility of light-emitting layer, and μe3 denoting electron mobility of electron transport layer satisfy

$$\frac{μ e 2}{μ e 3} \times exp ( - Δ E 2 \times 38.681731 ) \leq 4.367 \times {10}^{- 4}$$

$$when μ e 2 < μ e 3 , and satisfy$$

$$exp ( - Δ E 2 \times 38.681731 ) \leq 4.367 \times {10}^{- 4}$$

$$when μ e 2 \geq μ e 3 ,$$

and

ΔH denoting difference between HOMO energy level of light-emitting layer and HOMO energy level of electron transport layer, μh2, and μh3 denoting hole mobility of electron transport layer satisfy

$$\frac{μ h 3}{μ h 2} \times exp ( - Δ H \times 38.681731 ) \leq 2.090 \times {10}^{- 2}$$

$$when μ h 3 < μ h 2 , and satisfy$$

$$exp ( - Δ H \times 38.681731 ) \leq 2.090 \times {10}^{- 2}$$

$$when μ h 3 \geq μ h 2.$$

This application is based on an application No. 2016-068481 filed in Japan, the contents of which are hereby incorporated by reference.

### BACKGROUND OF THE DISCLOSURE

### (1) Technical Field

The present invention is related to a charge injection characteristic in an organic electroluminescence (EL) element.

### (2) Description of Related Art

Recently, organic EL elements are coming into use in display devices, lighting devices, and the like.

An organic EL element has an anode and a cathode, and at least a light-emitting layer between the anode and the cathode. Further, many organic EL elements have a structure where a hole transport layer is disposed between the anode and the light-emitting layer, and an electron transport layer is disposed between the light-emitting layer and the cathode.

The hole transport layer is formed by using a material with greater hole mobility than electron mobility (such a material referred to in the following as a hole transport material), and is provided for supplying the light-emitting layer with holes. Meanwhile, the electron transport layer is formed by using a material with greater electron mobility than hole mobility (such a material referred to in the following as an electron transport material), and is provided for supplying the light-emitting layer with electrons.

Further, when a voltage is applied between the anode and the cathode, the electron transport layer injects electrons into the lowest unoccupied molecular orbital (LUMO) of the light-emitting layer, and the hole transport layer injects holes into the highest occupied molecular orbital (HOMO) of the light-emitting layer. Here, the applied voltage causes an electric field to be generated in the light-emitting layer. This electric field causes the electrons injected into the LUMO of the light-emitting layer to move inside the light-emitting layer towards the anode, and causes the holes injected into the HOMO of the light-emitting layer to move inside the light-emitting layer towards the cathode. When electrons and holes recombine in the light-emitting layer due to the movement thereof described above, excitons are generated in the light-emitting layer. Light-emission occurs when these excitons return from the excited state to the ground state (as disclosed in Japanese Patent Application Publication No. 2004-514257).

### SUMMARY OF THE DISCLOSURE

### (1) Problem to be Solved

Meanwhile, organic EL element lifespan is dependent upon various factors. One of such factors is the degradation of the organic material used to form the light-emitting layer. In connection with this, it is known that driving of the organic EL element accelerates the degradation of the organic material. This is because a certain proportion of excitons generated due to the driving of the organic EL element become deactivated without emitting any light (such deactivation of an exciton referred to in the following as non-emission deactivation), and some of the energy held by the excitons undergoing non-emission deactivation become heat, vibration, and the like, which bring about degradation of the organic material.

Further, it is also known that typically, the distribution of excitons in a thickness direction of a light-emitting layer is biased towards the interface with the hole transport layer if the light-emitting layer is formed by using electron transport material, and is biased towards the interface with the electron transport layer if the light-emitting layer is formed by using hole transport material. (Note that in the following, unless mentioned otherwise, the term “distribution” is used to refer to a thickness-direction distribution). In either case, degradation of the organic material occurs at a particularly high rate where gathering of excitons is observed in the density distribution.

Such local degradation of organic material is considered to be a bottleneck in terms of light-emitting layer lifespan. In other words, the biasing of exciton density distribution towards one area of a light-emitting layer is a problem that needs to be overcome to achieve longevity of organic EL elements.

The present invention has been made in view of such problems, and aims to provide an organic EL element with a long lifespan.

### (2) Means for Solving Problem

In view of the aim described above, one aspect of the present invention is an organic electroluminescence (EL) element including: an anode; a hole transport layer above the anode, the hole transport layer containing a first organic semiconductor; a light-emitting layer on the hole transport layer, the light-emitting layer containing a second organic semiconductor; an electron transport layer on the light-emitting layer, the electron transport layer containing a third organic semiconductor; and a cathode above the electron transport layer, wherein the first organic semiconductor, the second organic semiconductor, and the third organic semiconductor each have a highest occupied molecular orbital (HOMO) and a lowest unoccupied molecular orbital (LUMO), the second organic semiconductor has higher electron mobility than hole mobility,

ΔE1 denoting a difference [eV] between a LUMO energy level of the first organic semiconductor and a LUMO energy level of the second organic semiconductor, μe1 denoting an electron mobility of the first organic semiconductor, and μe2 denoting an electron mobility of the second organic semiconductor satisfy

$$\frac{μ e 1}{μ e 2} \times exp ( - Δ E 1 \times 38.681731 ) \leq 2.090 \times {10}^{- 2} when μ e 1 < μ e 2 , \\ and$$

$$satisfy exp ( - Δ E 1 \times 38.681731 ) \leq 2.090 \times {10}^{- 2} when μ e 1 < μ e 2 ,$$

ΔE2 denoting a difference [eV] between the LUMO energy level of the second organic semiconductor and a LUMO energy level of the third organic semiconductor, μe2, and μe3 denoting an electron mobility of the third organic semiconductor satisfy

$$\frac{μ e 2}{μ o 3} \times exp ( - Δ E 2 \times 38.681731 ) \leq 4.367 \times {10}^{- 4} when μ e 2 < μ e 3 , \\ and$$

$$satisfy exp ( Δ E 2 \times 38.681731 ) \leq 4.367 \times {10}^{- 4} when μ e 2 \geq μ e 3 ,$$

and

ΔH denoting a difference [eV] between a HOMO energy level of the second organic semiconductor and a HOMO energy level of the third organic semiconductor, μh2 denoting a hole mobility of the second organic semiconductor, and μh3 denoting a hole mobility of the third organic semiconductor satisfy

$$\frac{ μ h 3}{μ h 2} \times exp ( - Δ H \times 38.681731 ) \leq 2.090 \times {10}^{- 2} when μ h 3 < μ h 2 , \\ and$$

$$satisfy exp ( - Δ H \times 38.681731 ) \leq 2.090 \times {10}^{- 2} when μ h 3 \geq μ h 2.$$

In view of the aim described above, another aspect of the present invention is an organic electroluminescence (EL) element including: an anode; a hole transport layer above the anode, the hole transport layer containing a first organic semiconductor; a light-emitting layer on the hole transport layer, the light-emitting layer containing a second organic semiconductor; an electron transport layer on the light-emitting layer, the electron transport layer containing a third organic semiconductor; and a cathode above the electron transport layer, wherein the first organic semiconductor, the second organic semiconductor, and the third organic semiconductor each have a highest occupied molecular orbital (HOMO) and a lowest unoccupied molecular orbital (LUMO), the second organic semiconductor has higher hole mobility than electron mobility,

ΔH1 denoting a difference [eV] between a HOMO energy level of the third organic semiconductor and a HOMO energy level of the second organic semiconductor, μh3 denoting a hole mobility of the third organic semiconductor, and μh2 denoting a hole mobility of the second organic semiconductor satisfy

$$\frac{ μ h 3}{μ h 2} \times exp ( - Δ H 1 \times 38.681731 ) \leq 2.090 \times {10}^{- 2} when μ h 3 < μ h 2 , \\ and$$

$$satisfy exp ( - Δ H 1 \times 38.681731 ) \leq 2.090 \times {10}^{- 2} when μ h 3 < μ h 2 ,$$

ΔH2 denoting a difference [eV] between the HOMO energy level of the second organic semiconductor and a HOMO energy level of the first organic semiconductor, μh2, and μh 1 denoting a hole mobility of the first organic semiconductor satisfy

$$\frac{ μ h 2}{μ h 1} \times exp ( - Δ H 2 \times 38.681731 ) \leq 4.367 \times {10}^{- 4 } when μ h 2 < μ h 1 , \\ and$$

$$satisfy exp ( - Δ H 2 \times 38.681731 ) \leq 4.367 \times {10}^{- 4 } when μ h 2 \geq μ h 1 ,$$

and

ΔE denoting a difference [eV] between a LUMO energy level of the second organic semiconductor and a LUMO energy level of the first organic semiconductor, μe2 denoting an electron mobility of the second organic semiconductor, and μe1 denoting an electron mobility of the first organic semiconductor satisfy

$$\frac{μ e 1}{μ e 2} \times exp ( - Δ E \times 38.681731 ) \leq 2.090 \times {10}^{- 2} when μ e 1 < μ e 2 , \\ and$$

$$satisfy exp ( - Δ E \times 38.681731 ) \leq 2.090 \times {10}^{- 2} when μ e 1 \geq μ e 2.$$

In view of the aim described above, another aspect of the present invention is an organic electroluminescence (EL) element including: an anode; a hole transport layer above the anode, the hole transport layer containing a first organic semiconductor; a light-emitting layer on the hole transport layer, the light-emitting layer containing a second organic semiconductor; an electron transport layer on the light-emitting layer, the electron transport layer containing a third organic semiconductor; and a cathode above the electron transport layer, wherein the first organic semiconductor, the second organic semiconductor, and the third organic semiconductor each have a highest occupied molecular orbital (HOMO) and a lowest unoccupied molecular orbital (LUMO), electron mobility and hole mobility of the second organic semiconductor are similar,

ΔE denoting a difference [eV] between a LUMO energy level of the first organic semiconductor and a LUMO energy level of the second organic semiconductor, μe1 denoting an electron mobility of the first organic semiconductor, and μe2 denoting an electron mobility of the second organic semiconductor satisfy

$$\frac{μ e 1}{μ e 2} \times exp ( - Δ E \times 38.681731 ) \leq 2.090 \times {10}^{- 2} when μ e 1 < μ e 2 , \\ and$$

$$satisfy exp ( - Δ E \times 38.681731 ) \leq 2.090 \times {10}^{- 2} when μ e 1 \geq μ e 2 ,$$

and

ΔH denoting a difference [eV] between a HOMO energy level of the second organic semiconductor and a HOMO energy level of the third organic semiconductor, μh2 denoting a hole mobility of the second organic semiconductor, and μh3 denoting a hole mobility of the third organic semiconductor satisfy

$$\frac{ μ h 3}{μ h 2} \times exp ( - Δ H \times 38.681731 ) \leq 2.090 \times {10}^{- 2} when μ h 3 < μ h 2 , \\ and$$

$$satisfy exp ( - Δ H \times 38.681731 ) \leq 2.090 \times {10}^{- 2} when μ h 3 < μ h 2.$$

In the light-emitting layer in the organic EL element pertaining to one aspect of the present invention, there are two exciton density peaks, each near a different one of the interface with the electron transport layer and the interface with the hole transport layer. Further, each of such density peaks is suppressed to be lower than the single exciton density peak of an light-emitting layer only having one exciton density peak near either the interface with the electron transport layer or the interface with the hole transport layer.

Thus, the organic EL element pertaining to one aspect of the present invention has a long lifespan, due to local degradation of the light-emitting layer being suppressed.

### BRIEF DESCRIPTION OF THE DRAWINGS

These and other objects, advantages, and features of the present invention will become apparent from the following description thereof taken in conjunction with the accompanying drawings, which illustrate at least one specific embodiment of the present invention.

FIG. 1 is a schematic illustrating the structure of an organic EL element pertaining to embodiment 1.

FIG. 2 is an energy band diagram illustrating an energy band structure in the organic EL element pertaining to embodiment 1.

FIGS. 3A through 3C illustrate exciton density distributions and recombination rates, with FIG. 3A corresponding to a comparative example, FIG. 3B corresponding to when ΔE2 is 0.14 [eV], and FIG. 3C corresponding to when ΔE2 is 0.325 [eV].

FIGS. 4A through 4C illustrate exciton density distributions and recombination rates, with FIG. 4A corresponding to when ΔE2 is 0.35 [eV], FIG. 4B corresponding to when ΔE2 is 0.44 [eV], and FIG. 4C corresponding to when ΔE2 is 0.5 [eV].

FIG. 5A is a graph illustrating a peak exciton density near an interface with a hole transport layer, for the comparative example and each of different values of the energy barrier ΔE2, FIG. 5B is a graph illustrating a peak exciton density near an interface with an electron transport layer, for the comparative example and each of the different values of the energy barrier ΔE2, and FIG. 5C is a graph illustrating an exciton density ratio, for the comparative example and each of the different values of the energy barrier ΔE2.

FIG. 6A is a graph illustrating a peak recombination rate near the interface with the hole transport layer, for the comparative example and each of the different values of the energy barrier ΔE2, FIG. 6B is a graph illustrating a peak recombination rate near the interface with the electron transport layer, for the comparative example and each of the different values of the energy barrier ΔE2, and FIG. 6C is a graph illustrating a recombination rate ratio, for the comparative example and each of the different values of the energy barrier ΔE2.

FIG. 7A is a graph illustrating the relationship between values of ΔE2 and exciton density ratios, and FIG. 7B is a graph illustrating the relationship between values of parameter P2 and the exciton density ratios.

FIG. 8 is a table illustrating how mobility ratio μy/μx and exp(−qφ/kT) calculated by using energy barrier φ are equivalent to one another.

FIG. 9A is a graph showing hole density distributions near an interface between a light-emitting layer and the electron transport layer for different values of energy barrier ΔH, and FIG. 9B is a graph showing the relationship between the energy barrier ΔH and a peak hole density in the light-emitting layer.

FIG. 10A is a graph showing recombination rates near the interface between the light-emitting layer and the electron transport layer for the different values of the energy barrier ΔH, and FIG. 10B is a graph showing the relationship between the energy barrier ΔH and a peak recombination rate in the light-emitting layer.

FIG. 11 is an energy band diagram illustrating an energy band structure in an organic EL element pertaining to modification 1.

FIG. 12 is a cross-sectional view illustrating a part of an organic EL display panel pertaining to embodiment 2.

FIGS. 13A through 13F are schematic partial cross-sectional views illustrating procedures in an organic EL display element manufacturing process pertaining to embodiment 2, with FIG. 13A illustrating a TFT substrate, FIG. 13B illustrating a state where anodes have been formed on the TFT substrate, FIG. 13C illustrating a state where a bank layer has been formed on the TFT substrate and the anodes, FIG. 13D illustrating a state where, in each opening in the bank layer, a hole injection layer has been formed on the anode, FIG. 13E illustrating a state where, in each opening in the bank layer, a hole transport layer has been formed on the hole injection layer, and FIG. 13F illustrating a state where, in each opening in the bank layer, a light-emitting layer has been formed on the hole transport layer.

FIGS. 14A through 14D are schematic partial cross-sectional views illustrating procedures subsequent to those illustrated in FIGS. 13A through 13F in the organic EL display element manufacturing process pertaining to embodiment 2, with FIG. 14A illustrating a state where an electron transport layer has been formed on the light-emitting layers and the bank layer, FIG. 14B illustrating a state where an electron injection layer has been formed on the electron transport layer, FIG. 14C illustrating a state where a counter electrode has been formed on the electron transport layer, and FIG. 14D illustrating a state where a sealing layer has been formed on the counter electrode.

FIG. 15 is a block diagram illustrating the structure of an organic EL display device including the organic EL display panel pertaining to embodiment 2.

### DESCRIPTION OF EMBODIMENTS

The following describes an organic EL element pertaining to one embodiment of the present invention. Note that the following describes an example for explaining the structure and effects pertaining to one aspect of the present invention, and thus, the present invention shall not be construed as being limited to the following description, other than essential aspects of the present invention described in the embodiments below.

### Embodiment 1

### 1. Organic EL Element Structure

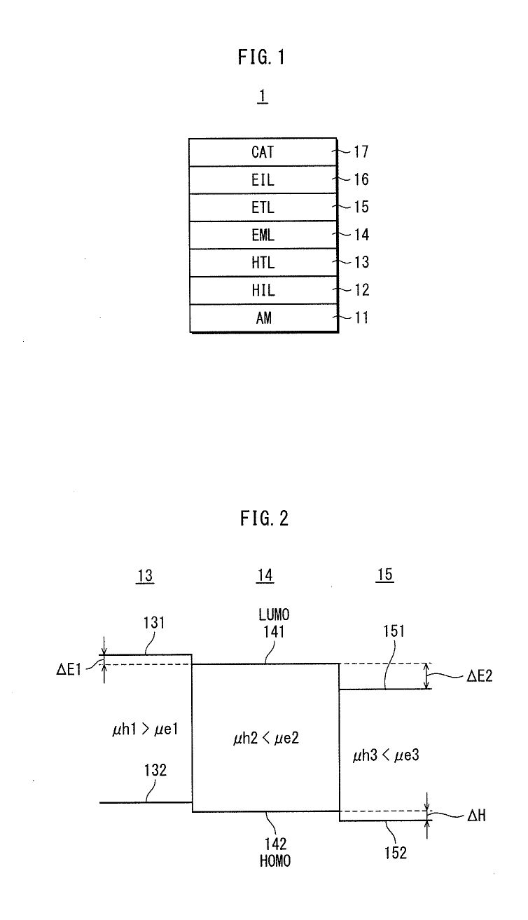

FIG. 1 is a schematic illustrating the cross-sectional structure of an organic EL element 1 pertaining to this embodiment. The organic EL element 1 includes an anode (AM) 11, a hole injection layer (HIL) 12, a hole transport layer (HTL) 13, a light-emitting layer (EML) 14, an electron transport layer (ETL) 15, an electron injection layer (EIL) 16, and a cathode (CAT) 17.

In the organic EL element 1, the hole transport layer 13 is disposed above the anode 11, the light-emitting layer 14 is disposed on the hole transport layer 13, the electron transport layer 15 is disposed on the light-emitting layer 14, and the cathode 17 is disposed above the electron transport layer 15.

The hole injection layer 12 promotes hole injection from the anode 11 to the light-emitting layer 14.

The hole transport layer 13 contains a first organic semiconductor. As the first organic semiconductor, a known organic material that is a hole transport material can be used. The hole transport layer 13 transports, to the light-emitting layer 14, holes injected thereto from the hole injection layer 12.

The light-emitting layer 14 is disposed between the hole transport layer 13 and the electron transport layer 15, and is in contact with both the hole transport layer 13 and the electron transport layer 15. The light-emitting layer 14 emits light when holes and electrons recombine therein. The light-emitting layer 14 contains a second organic semiconductor. As the second organic semiconductor, a known organic material that is an electron transport material can be used.

The electron transport layer 15 contains a third organic semiconductor. As the third organic semiconductor, a known organic material that is an electron transport material can be used. The electron transport layer 15 transport, to the light-emitting layer 14, electrons injected thereto from the electron transport layer 16.

The electron injection layer 16 is a functional layer containing a metal or a metal oxide. The electron injection layer 16 promotes electron injection from the cathode 17 to the electron transport layer 15.

The organic EL element 1 has the structure described up to this point.

### 2. Carrier Accumulation Characteristic

For the forming of excitons, it is necessary to put electrons and holes in close distance to one another. Further, it is known that typically, the position where excitons are formed is correlated with the density distribution of electrons and holes in the organic EL element 1 in the steady state.

In the light-emitting layer 14, accumulation of charge carriers (electrons/holes) occurs at the interface with the hole transport layer 13 and the interface with the electron transport layer 15. In view of this, the inventors investigated the characteristic of carrier accumulation at these interfaces by using a model device prepared by combining an organic semiconductor X and an organic semiconductor Y. Here, the following case is considered: the organic semiconductor X and the organic semiconductor Y have carrier mobilities of μx and μy, respectively, and an electric field E is applied to cause carriers to be injected from the organic semiconductor X to the organic semiconductor Y.

For example, according to the Poole-Frenkel mobility model regarding carrier mobility in an organic semiconductor, in the model device described above, the organic semiconductor X may start injecting new carriers into the organic semiconductor Y before the diffusion of carriers in the organic semiconductor Y, from the trap sites near the interface with the organic semiconductor X to the electrode located at the opposite side of the organic semiconductor Y, is completed, should mobility μy be smaller than mobility μx. When this occurs, the injection of new carriers is blocked, and thus, injection current J from the organic semiconductor X to the organic semiconductor Y is restricted. Hence, carrier accumulation occurs in the organic semiconductor X near the interface with the organic semiconductor Y.

Accordingly, it can be considered that the carrier accumulation characteristic in the organic semiconductor X near the interface with the organic semiconductor Y is correlated with the level of the injection current J.

Conventionally, the thermionic emission-diffusion model is known as a model regarding charge injection at an interface between a metal and a semiconductor. According to the thermionic emission-diffusion model, the injection current J is expressible by Math 1.

$$J = q \times μ \times Nc \times E \times exp ( - \frac{q ϕ}{kT} ) \times exp ( \frac{q}{kT} \times γ \times \sqrt{E} ) \qquad ( Math 1 )$$

In Math. 1, φ denotes a carrier injection energy barrier at the interface, μ denotes semiconductor carrier mobility, k denotes the Boltzmann's constant, and T denotes temperature.

According to Math 1, the injection current J is dependent upon mobility μ as well as energy barrier φ. Here, Math 3 can be obtained by substituting Math 2 for mobility μ in Math 1. Math 2 represents the Poole-Frenkel mobility model regarding carrier mobility in an organic semiconductor.

$$\begin{matrix} μ = μ0 \times exp ( - \frac{ɛ a}{kT} ) \times exp ( \frac{q}{kT} \times β \sqrt{E} ) & ( Math 2 ) \\ J = q \times μ0 \times Nc \times E \times exp \{ - \frac{( ɛ a + q ϕ )}{kT} \} \times exp \{ \frac{q}{kT} \times ( β + γ ) \times \sqrt{E} \} & ( Math 3 )\end{matrix}$$

In Maths 2 and 3, εa denotes activation energy of trapped carriers in an organic semiconductor when there is no electric field (activation energy of trapped carriers is referred to in the following simply as activation energy), and μ0 denotes a constant with which mobility is achieved by μ0×exp(−εa/kT) with no electric field.

This means that the injection current J is proportional to exp{−(εa+qφ)/kT}, as expressed by Math 4.

$$J ∝ exp \{ - \frac{( ɛ a + q ϕ )}{kT} \} \qquad ( Math 4 )$$

Accordingly, it can be considered that in Math 3, the influence of the activation energy εa on the injection current J and the influence of the injection barrier φ on the injection current J are equal.

As already described above, Math 3 is based on the thermionic emission-diffusion model regarding charge injection at an interface between a metal and a semiconductor. In order to expand this to the model device, which is a combination of the organic semiconductors X and Y, the relationship εa=εay−εax is introduced, where εax denotes the assumed activation energy for organic semiconductor X when there is no electric field and εay denotes the assumed activation energy for organic semiconductor Y when there is no electric field. Accordingly, Math 3 can be rewritten as Math 5.

$$J = q \times μ0 \times Nc \times E \times exp \{ - \frac{( ɛ ay - ɛ ax )}{kT} \} \times exp ( - \frac{q ϕ}{kT} ) \times exp \{ \frac{q}{kT} \times ( β + γ ) \times \sqrt{E} \} \qquad ( Math 5 )$$

Further, by introducing activation energy sax and activation energy say into Math 2 representing the Poole-Frenkel mobility model, μx and μy respectively denoting the carrier mobility in organic semiconductor X and the carrier mobility in organic semiconductor Y, can be expressed by Math 6 and Math 7, respectively.

$$\begin{matrix}μ x = μ 0 \times exp ( - \frac{ɛ ax}{kT} ) \times exp ( \frac{q}{kT} \times β \times \sqrt{E} ) & ( Math 6 ) \\ μ y = μ 0 \times exp ( - \frac{ɛ ay}{kT} ) \times exp ( \frac{q}{kT} \times β \times \sqrt{E} ) & ( Math 7 )\end{matrix}$$

When supposing that, the value of μ0, which is a constant regarding mobility with no electric field, and the value of electric field coefficient β does not change between Math 6 and Math 7, Math 8 can be obtained. Math 8 expresses the relationship between ratio μy/μx (ratio of mobility μy to mobility μx) and activation energy. (Note that in the following, a ratio of a mobility of a carrier injection destination to a mobility of a carrier injection source is referred to as a mobility ratio.)

$$\frac{μ y}{μ x} = exp ( - \frac{ɛ ay - ɛ ax}{kT} ) \qquad ( Math 8 )$$

Based on the relationship between activation energy and mobility ratio μy/μx indicated by Math 8, Math 5 can be rewritten as Math 9.

$$J = q \times μ0 \times Nc \times E \times \frac{μ y}{μ x} \times exp ( - \frac{q ϕ}{kT} ) \times exp \{ \frac{q}{kT} \times ( β + γ ) \times \sqrt{E} \} \qquad ( Math 9 )$$

As such, Math 4, when expanded to the model device described above, can be rewritten as Math 10.

$$J ∝ \frac{μ y}{μ x} \times exp ( - \frac{q ϕ}{kT} ) \qquad ( Math 10 )$$

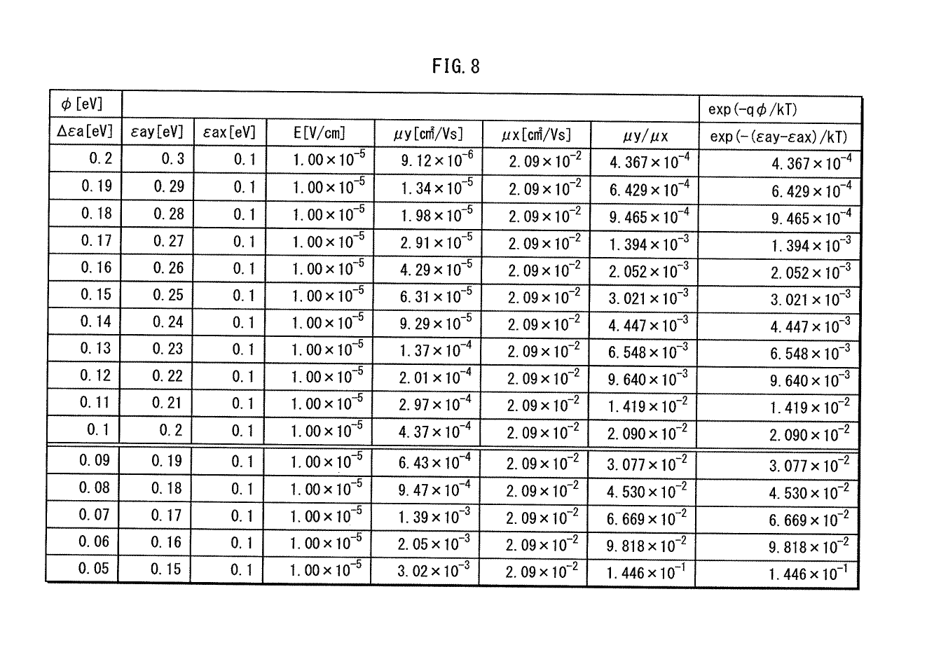

Hence, it can be considered that the influence of mobility ratio μy/μx on the injection current J and the influence of exp(−qφ/kT), which incorporates the injection barrier φ, on the injection current J are equal. For example, the values of exp(−qφ/kT) within the range from 0.05 to 0.2 can be associated with values of μy/μx as illustrated in the table in FIG. 8. The values of exp(−qφ/kT) in the table are those calculated for a case when the electric field E is 1.00×10⁻⁵ [cm²/Vs], and were calculated based on the injection barrier φ by setting 1.602176565×10⁻¹⁹ [C] to the elementary charge q, setting 1.3806488×10⁻²³ [J/K] to the Boltzmann's constant k, and setting 300 [K] to the temperature T.

As shown by the row in the table emphasized with double underline, when the electric field E is 1.00×10⁻⁵ [cm²/Vs], the influence that an injection barrier φ of 0.1 [eV] has on the injection current J and the influence that a mobility ratio μy/μx of 2.090×10⁻² has on the injection current J are equal. Based on this, in order to achieve an injection current J corresponding to when the injection barrier φ is 0.1 [eV] when the injection barrier φ is actually 0 [eV] with the mobility μx of the organic semiconductor X being 2.090×10⁻², it suffices to use, as the organic semiconductor Y, an organic material whose mobility μy is 4.37×10⁻⁴.

As described above, carrier accumulation characteristic of the organic semiconductor X near the interface with the organic semiconductor Y can be considered to be correlated with the level of the injection current J. Thus, it can be considered that the carrier accumulation characteristic of the organic semiconductor X near the interface with the organic semiconductor Y is influenced by the product of μy/μx and exp(−qφ/kT) (referred to in the following as parameter P).

The parameter P, as shown by the three equations in Math 11, is indicative of carrier injection and carrier accumulation. Specifically, the smaller the mobility μy of the injection destination organic semiconductor Y is compared to the mobility μx of the injection source organic semiconductor X, the smaller the parameter P and thus the more difficult the injection of carriers from the organic semiconductor X to the organic semiconductor Y. Thus, carrier accumulation in the organic semiconductor X near the interface with the organic semiconductor Y increases. Also, the greater the injection barrier φ, the smaller the parameter P and thus the more difficult the injection of carriers from the organic semiconductor X to the organic semiconductor Y. Again, the carrier accumulation in the organic semiconductor X near the interface with the organic semiconductor Y thus increases.

$$Γ = \frac{μ y}{μ x} \times exp ( - \frac{q ϕ}{kT} ) \\ P = \frac{μ y}{μ x} \times exp ( - \frac{1.602176565 \times {10}^{- 19} [ J \text{/} eV ] \times ϕ [ eV ]}{300 [ K ] \times 1.3806488 \times {10}^{- 23} [ J \text{/} K ]} ) \\ P = \frac{μ y}{μ x} \times exp ( - 38.681731 \times ϕ ) \qquad ( Math 11 )$$

In view of the above, in the organic EL element 1 pertaining to this embodiment, the organic materials that are used for the first, second, and third organic semiconductors are selected so that parameters P1, P2, and P3 have values within the respective ranges described later in the present disclosure. Specifically, parameter P1 is related to the injection of electrons from the light-emitting layer 14 to the hole transport layer 13, parameter P2 is related to the injection of electrons from the electron transport layer 15 to the light-emitting layer 14, and parameter P3 is related to the injection of holes from the light-emitting layer 14 to the electron transport layer 15.

Note that when the injection destination mobility μy is smaller than the injection source mobility μx (i.e., when μy<μa is satisfied), the carriers in the injection destination organic semiconductor Y cannot easily diffuse from the trap sites near the interface with the organic semiconductor X. Thus, carrier injection from the organic semiconductor X to the organic semiconductor Y is difficult. Due to this, not only the injection barrier φ but also the mobility ratio μy/μx influences carrier injection and carrier accumulation.

Meanwhile, when the injection destination mobility μy is greater than or equal to the injection source mobility μx (i.e., when μy≧μx is satisfied), the diffusion of carriers from the trap sites in the organic semiconductor Y near the interface with the organic semiconductor X is greater than or equal to the supply of carriers to the trap sites. Due to this, there is no difficulty of carrier injection to the organic semiconductor Y due to the shortage of vacant trap sites, and thus, the mobility ratio μy/μx does not influence carrier injection or carrier accumulation. In this case, the mobility ratio μy/μx in the parameter P is deemed as being equal to 1, and thus the parameter P is solely dependent upon the injection barrier φ.

Due to this, when electron mobility μe1 is smaller than electron mobility μe2 and thus μe1/μe2 influences electron injection from the light-emitting layer 14 to the hole transport layer 13, the parameter P1 can be expressed by Math 12, using the energy barrier ΔE1, the electron mobility μe1 of the hole transport layer 13, and the electron mobility μe2 of the light-emitting layer 14, each of which is illustrated in the energy band diagram in FIG. 2.

$$P 1 = \frac{μ e 1}{μ e 2} \times exp ( 38.681731 \times Δ E 1 ) \qquad ( Math 12 )$$

Meanwhile, when electron mobility μe1 is greater than or equal to electron mobility μe2 and thus μe1/μe2 does not influence electron injection from the light-emitting layer 14 to the hole transport layer 13, the parameter P1 can be expressed by Math 13, using the energy barrier ΔE1.

P1=exp(−38.681731×ΔE1) (Math 13)

Further, when electron mobility μe2 is smaller than electron mobility μe3 and thus μe2/μe3 influences electron injection from the electron transport layer 15 to the light-emitting layer 14, the parameter P2 can be expressed by Math 14, using the energy barrier ΔE2, the electron mobility μe2 of the light-emitting layer 14, and the electron mobility μe3 of the electron transport layer 15.

$$P 1 = \frac{μ e 2}{μ e 3} \times exp ( - 38.681731 \times Δ E 2 ) \qquad ( Math 14 )$$

Meanwhile, when electron mobility μe2 is greater than or equal to electron mobility μe3 and thus μe2/μe3 does not influence electron injection from the electron transport layer 15 to the light-emitting layer 14, the parameter P2 can be expressed by Math 15, using the energy barrier ΔE2.

P2=exp(−38.681731×ΔE2) (Math 15)

Further, when hole mobility μh3 is smaller than hole mobility μh2 and thus μh3/μh2 influences hole injection from the light-emitting layer 14 to the electron transport layer 15, the parameter P3 can be expressed by Math 16, using the energy barrier ΔH, the hole mobility μh3 of the electron transport layer 15, and the hole mobility μh2 of the light-emitting layer 14.

$$P 3 = \frac{μ h 3}{μ h 2} \times exp ( 38.681731 \times Δ H ) \qquad ( Math 16 )$$

Meanwhile, when hole mobility μh3 is greater than or equal to hole mobility μh2 and thus μh3/μh2 does not influence hole injection from the light-emitting layer 14 to the electron transport layer 15, the parameter P3 can be expressed by Math 17, using the energy barrier ΔH.

P3=exp(−38.681731×ΔH) (Math 17)

Note that in FIG. 2, the LUMO energy level and the HOMO energy level of the first organic semiconductor are respectively illustrated as a LUMO energy level 131 and a HOMO energy level 132 of the hole transport layer 13, the LUMO energy level and the HOMO energy level of the second organic semiconductor are respectively illustrated as a LUMO energy level 141 and a HOMO energy level 142 of the light-emitting layer 14, and the LUMO energy level and the HOMO energy level of the third organic semiconductor are respectively illustrated as a LUMO energy level 151 and a HOMO energy level 152 of the electron transport layer 15. Note that in the following, the LUMO energy level and the HOMO energy level of an organic semiconductor contained in a given layer is referred to as the LUMO energy level and the HOMO energy level of the layer.

### 3. Parameter P2

The inventors investigated an appropriate value for the parameter P2 by conducting a simulation calculation of exciton density distribution and recombination rate distribution in a film thickness direction of the organic EL element 1.

First, as a comparative example, the inventors conducted a simulation calculation of exciton density distribution and recombination rate in an organic EL element where the energy barrier ΔE1 is 0.26 [eV], the energy barrier ΔE2 is 0.01 [eV], and the energy barrier ΔH is 0 [eV]. In this calculation experiment, the inventors set the mobility ratio μe1/μe2 (i.e., the ratio of the electron mobility μe1 of the hole transport layer to the electron mobility μe2 of the light-emitting layer) to 4.444×10¹, set the mobility ratio μe2/μe3 (i.e., the ratio of the electron mobility μe2 of the light-emitting layer to the electron mobility μe3 of the electron transport layer) to 9.818×10⁻², and set the mobility ratio μh3/μh2 (i.e., the ratio of the hole mobility Δh3 of the electron transport layer to the hole mobility μh2 of the light-emitting layer) to 6.667×10⁻¹. Further, the inventors set the electron mobility μe2 in the light-emitting layer to around three times the hole mobility Δh2 in the light-emitting layer.

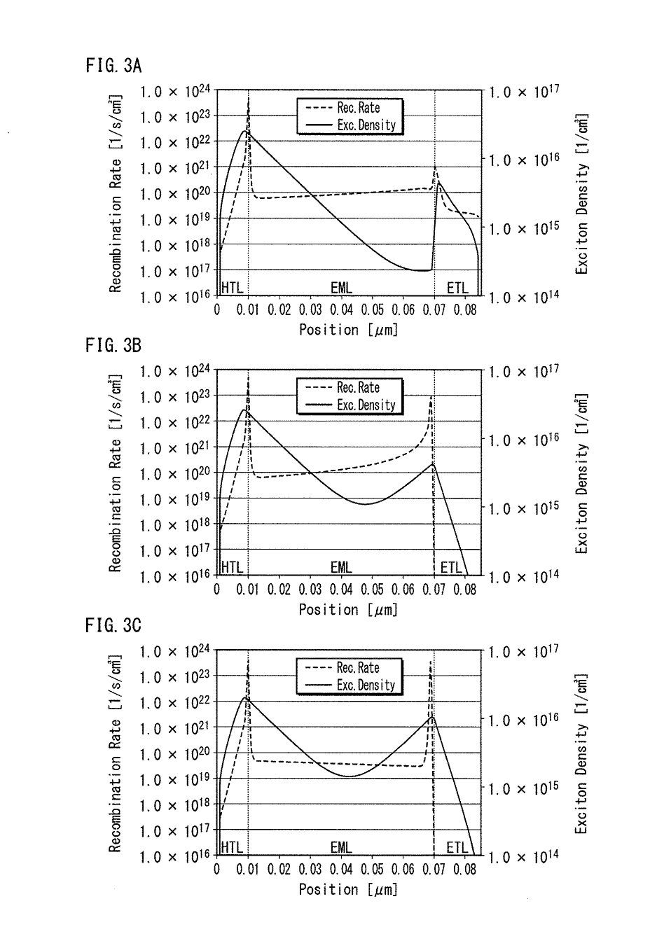

As a result, in the comparative example, the exciton density in the light-emitting layer was greatest at the interface with the hole transport layer, and decreased with closer distance to the electron transport layer, as illustrated in FIG. 3A. In particular, no peak was observed in the exciton density distribution at the interface with the electron transport layer.

A similar trend was observed for recombination rate, and greatest recombination rate in the light-emitting layer was observed near the interface with the hole transport layer. Further, a peak recombination rate was observed in the electron transport layer side of the interface between the light-emitting layer and the electron transport layer, and the recombination rate at the light-emitting layer side of the interface was low.

Based on such results, it can be expected that light-emitting layer degradation will occur near the interface with the hole transport layer, where a peak was observed in both exciton density and recombination rate.

The inventors also conducted a simulation calculation of the organic EL element 1 pertaining to the present embodiment. Specifically, in this simulation calculation, the inventors simulated exciton density distribution and recombination rate by setting a fixed value 0.26 [eV] to the energy barrier ΔE1, setting a fixed value 0.47 [eV] to the energy barrier ΔH, and by setting various values to the energy barrier ΔE2. In the simulation calculation, the inventors set the mobility ratio μe1/μe2 (i.e., the ratio of the electron mobility μe1 of the hole transport layer 13 to the electron mobility μe2 of the light-emitting layer 14) to 4.444×10¹, set the mobility ratio μe2/μe3 (i.e., the ratio of the electron mobility μe2 of the light-emitting layer 14 to the electron mobility μe3 of the electron transport layer 15) to 9.818×10⁻², and set the mobility ratio μh3/μh2 (i.e., the ratio of the hole mobility μh3 of the electron transport layer 15 to the hole mobility μh2 of the light-emitting layer 14) to 6.667×10⁻¹. Further, the inventors set the electron mobility μe2 in the light-emitting layer 14 to around three times the hole mobility μh2 in the light-emitting layer 14.

The energy barrier ΔE2 is the difference between the LUMO energy level 141 of the light-emitting layer 14 and the LUMO energy level 151 of the electron transport layer 15, and thus, is an injection barrier to be overcome in electron injection from the electron transport layer 15 to the light-emitting layer 14. Through setting various values to this energy barrier ΔE2, the inventors confirmed that the energy barrier ΔE2 influences the balance between the excitons accumulated in the light-emitting layer 14 near the interface with the hole transport layer 13 and the excitons accumulated in the light-emitting layer 14 near the interface with the electron transport layer 15.

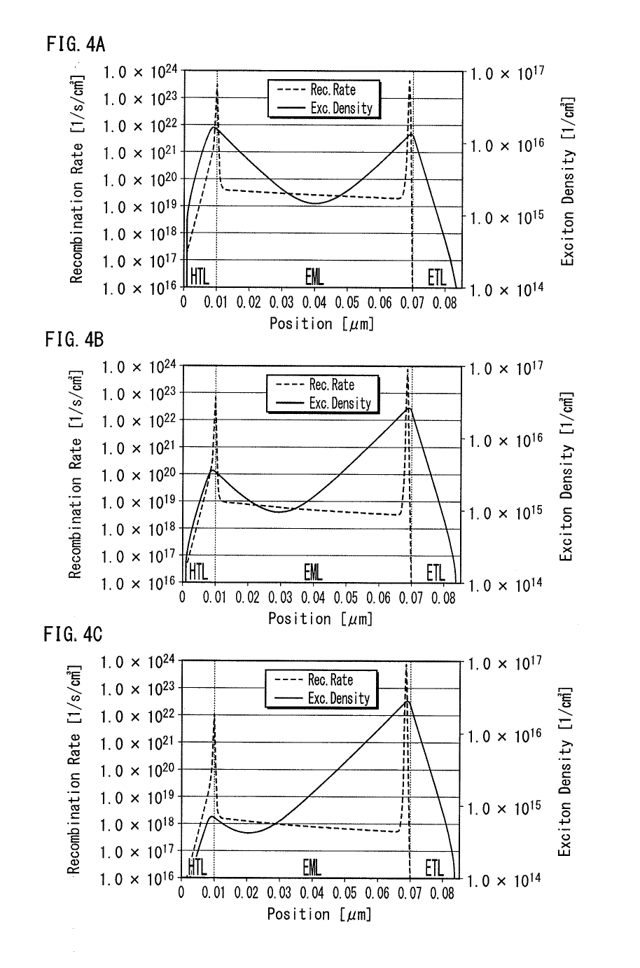

FIGS. 3B and 3C and FIGS. 4A through 4C illustrate exciton density distributions and recombination rates obtained through the simulation calculation of the organic EL element 1. FIG. 3B corresponds to when the energy barrier ΔE2 was set to 0.14 [eV], FIG. 3C corresponds to when the energy barrier ΔE2 was set to 0.325 [eV], FIG. 4A corresponds to when the energy barrier ΔE2 was set to 0.35 [eV], FIG. 4B corresponds to when the energy barrier ΔE2 was set to 0.44 [eV], and FIG. 4C corresponds to when the energy barrier ΔE2 was set to 0.5 [eV].

Referring for example to the case when the energy barrier ΔE2 was set to 0.14 [eV], the exciton density distribution in the light-emitting layer 14 not only had a peak near the interface with the hole transport layer 13, but also had a peak near the interface with the electron transport layer 15, as illustrated in FIG. 3B. A similar trend was observed for recombination rate, and the recombination rate in the light-emitting layer 14 not only had a peak near the interface with the hole transport layer 13 but also had a peak near the interface with the electron transport layer 15.

When yielding the same light-emission luminance with both the comparative example and the organic EL element 1, the values of the two peaks in the case where ΔE2 was set to 0.14 [eV] would both be lower than the value of the single peak in the comparative example. Accordingly, it can be considered that in when the energy barrier ΔE2 is set to 0.14 [eV], the degradation of the light-emitting layer 14 near the interface with the hole transport layer 13 is smaller compared to in the comparative example.

Further, when ΔE2 was increased to 0.325 [eV], for both the exciton density distribution and the recombination rate, the peak value near the interface with the hole transport layer 13 decreased and the peak value near the interface with the electron transport layer 15 increased as illustrated in FIG. 3C, compared to when ΔE2 was set to 0.14 [eV]. When ΔE2 was further increased to 0.35 [eV], for both the exciton density distribution and the recombination rate, the peak value near the interface with the hole transport layer 13 and the peak value near the interface with the electron transport layer 15 became similar values, as illustrated in FIG. 4A.

In order to analyze the influence of the increase in ΔE2 on exciton density distribution and recombination rate in detail, the inventors organized the results of the simulation calculation as described in the following.

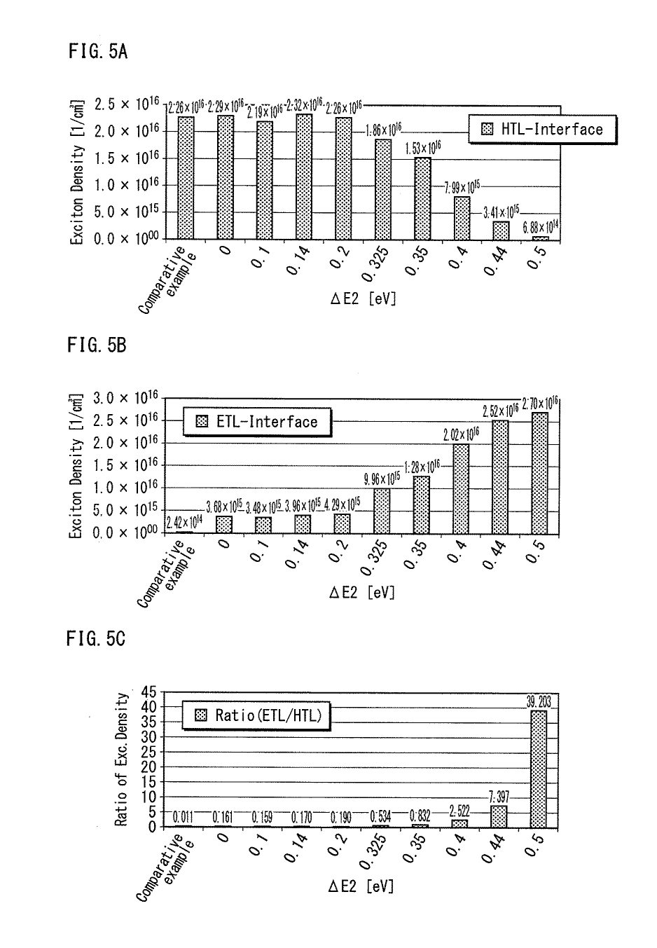

FIG. 5A is a graph illustrating the peak exciton density in the light-emitting layer 14 near the interface with the hole transport layer 13, for the comparative example and each of the different values of the energy barrier ΔE2. FIG. 5B is a graph illustrating the peak exciton density in the light-emitting layer 14 near the interface with the electron transport layer 15, for the comparative example and each of the different values of the energy barrier ΔE2. FIG. 5C is a graph illustrating a ratio of the peak exciton density in the light-emitting layer 14 near the interface with the electron transport layer 15 to the peak exciton density in the light-emitting layer 14 near the interface with the hole transport layer 13 (this ratio is referred to in the following as exciton density ratio), for the comparative example and each of the different values of the energy barrier ΔE2.

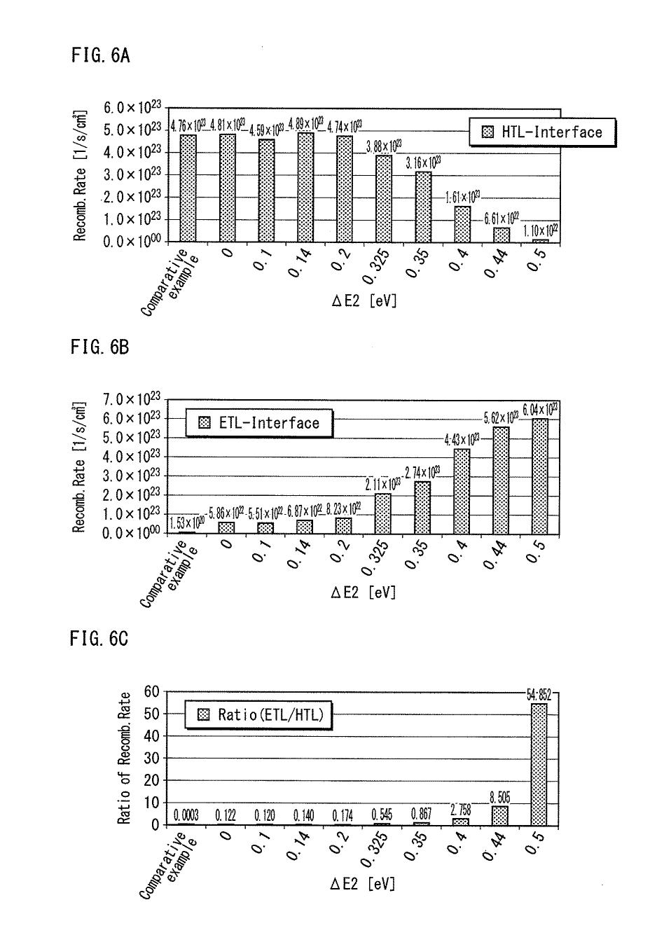

Further, FIG. 6A is a graph illustrating the peak recombination rate in the light-emitting layer 14 near the interface with the hole transport layer 13, for the comparative example and each of the different values of the energy barrier ΔE2. FIG. 6B is a graph illustrating the peak recombination rate in the light-emitting layer 14 near the interface with the electron transport layer 15, for the comparative example and each of the different values of the energy barrier ΔE2. Further, FIG. 6C is a graph illustrating a ratio of the peak recombination rate in the light-emitting layer 14 near the interface with the electron transport layer 15 to the peak recombination rate in the light-emitting layer 14 near the interface with the hole transport layer 13 (this ratio is referred to in the following as recombination rate ratio), for the comparative example and each of the different values of the energy barrier ΔE2.

FIGS. 5A and 5B and FIGS. 6A and 6B show that for both exciton density and recombination ratio, the peak value near the interface with the hole transport layer 13 tended to decrease and the peak value near the interface with the electron transport layer 15 tended to increase as the value of ΔE2 increased.

Meanwhile, FIGS. 5C and 6C show that the exciton density ratio and the recombination rate ratio both tended to increase as the value of ΔE2 increased.

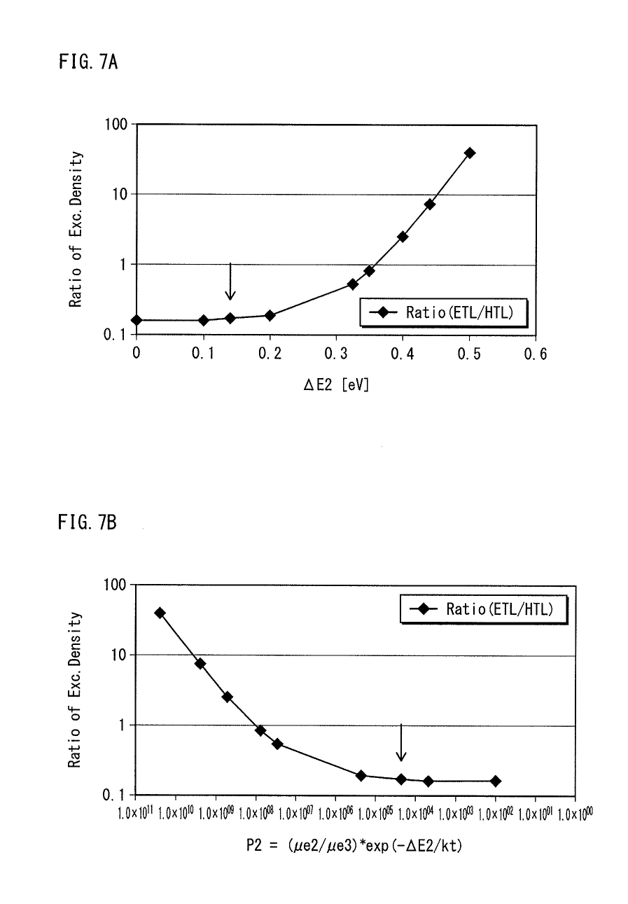

The following investigates an appropriate value range for each of ΔE2 and the parameter P2, with reference to FIGS. 7A and 7B. FIG. 7A is a graph illustrating the relationship between the values of ΔE2 and exciton density ratios in the simulation calculation of the organic EL element 1. FIG. 7B is a graph illustrating the relationship between values of the parameter P2 and the exciton density ratios.

From the graph in FIG. 7A, it can be seen that the change in exciton density ratio brought about by increasing ΔE2 is small when ΔE2 is 0 [eV] or greater and smaller than 0.14 [eV]. Thus, it can be considered that with ΔE2 within this range, not much improvement can be made of the tendency of the exciton density distribution in the light-emitting layer 14 being greatly biased towards the vicinity of the interface with the hole transport layer 13.

However, when ΔE2 becomes 0.14 [eV] or greater, the change in exciton density ratio brought about by increasing ΔE2 becomes greater. In particular, the increase in exciton density ratio becomes prominent when ΔE2 becomes 0.325 [eV] or greater Further, the exciton density ratio when ΔE2 is 0.35 [eV] is 0.832, from which it can be seen that the density of excitons near the interface with the hole transport layer 13 and density of excitons near the interface with the electron transport layer 15 are substantially similar.

When ΔE2 is increased even further, the exciton density ratio reaches 7.397 when ΔE2 is 0.44 [eV]. However, this value is close to the value 6.211, which is the inverse of the exciton density ratio 0.161 when ΔE2 is 0 [eV]. From this, it can be seen that when a value greater than 0.44 [eV] is set to ΔE2, the exciton density distribution becomes excessively biased towards the interface with the electron transport layer 15, and thus, the lifespan of the organic EL element 1 in this case becomes shorter than the lifespan when ΔE2 is 0 [eV].

As such, in the simulation calculation, the crowding of excitons near the interface with the hole transport layer 13 was moderated and thus longevity of the organic EL element 1 was achieved when ΔE2 was no smaller than 0.14 [eV]. The value range of parameter P2 corresponding to this range of ΔE2 is 4.367×10⁻⁴ or smaller according to Math 14, due to the mobility ratio μe2/μe3 used in the calculation experiment being 9.818×10⁻². Accordingly, it can be concluded that it is preferable to set a value 4.367×10⁻⁴ or smaller to the parameter P2.

Further, in the simulation calculation, it was also observed that setting a value greater than 0.44 [eV] to ΔE2 leads to the exciton distribution being excessively biased towards the interface with the electron transport layer 15. Thus, in order to achieve longevity, it is preferable that ΔE2 be set to a value no smaller than 0.14 [eV] and no greater than 0.44 [eV]. The value range of parameter P2 corresponding to this range of ΔE2 is 3.984×10⁻⁹ or greater and 4.367×10⁻⁴ or smaller according to Math 14. Accordingly, it can be concluded that it is preferable to set a value 3.984×10⁻⁹ or greater and 4.367×10⁻⁴ or smaller to the parameter P2.

Further, from the results of the simulation calculation, it can be considered that when setting a value 0.325 [eV] or greater to ΔE2, the effect of improving the balance of the exciton density distribution becomes more prominent and thus the effect of achieving longevity also becomes more prominent compared to when setting a value smaller than 0.325 [eV] to ΔE2. In particular, the density of excitons near the interface with the hole transport layer 13 and the density of excitons near the interface with the electron transport layer 15 become substantially similar when ΔE2 is 0.35 [eV]. Thus, maximum longevity of the organic EL element 1 can be achieved when setting ΔE2 to 0.35 [eV]. Based on this, it is further preferable that a value no smaller than 0.325 [eV] and no greater than 0.35 [eV] be set to ΔE2. The value range of parameter P2 corresponding to this range of ΔE2 is 1.295×10⁻⁷ or greater and 3.406×10⁻⁷ or smaller according to Math 14. Accordingly, it can be concluded that it is preferable to set a value 1.295×10⁻⁷ or greater and 3.406×10⁻⁷ or smaller to the parameter P2.

Note that the ease with which excitons can leave the light-emitting layer 14 for the hole transport layer 13 and the electron transport layer 15 is dependent upon exciton lifespan and exciton diffusion length in each of the hole transport layer 13, the light-emitting layer 14, and the electron transport layer 15. Typically, in order to achieve a practical level of luminous efficacy, materials for these layers are selected so that excitons cannot easily leave the light-emitting layer 14 for the hole transport layer 13 and the electron transport layer 15. Thus, in the simulation calculation described above, the exciton lifespan and the exciton diffusion length in each of the hole transport layer 13 and the electron transport layer 15 were set so that the excitons from the light-emitting layer 14 cannot easily diffuse into these layers.

Further, in the simulation calculation, the exciton diffusion length in the light-emitting layer 14 was set to 10 [nm]. However, no change in exciton density ratios for different values of ΔE2 were observed even when the exciton diffusion length was changed from 10 [nm]. Due to this, it can be concluded that the influence that the exciton diffusion length in the light-emitting layer 14 has on the preferable value range of the parameter P2 is ignorably small.

Further, as described above, the electron mobility μe2 in the light-emitting layer 14 was set to about three times the hole mobility μh2 in the light-emitting layer 14. Here, it should be noted that these values of electron mobility μe2 and hole mobility μh2 were set considering typical values in an organic material practically selectable as the second organic semiconductor. In the organic EL element 1 pertaining to this embodiment, any value can be set to each of the electron mobility μe2 and hole mobility μh2 as long as the ratio μe2/μh2 indicating the ratio of the electron mobility μe2 to the hole mobility μh2 in the second organic semiconductor has a value no smaller than 2.

Meanwhile, when the electron mobility μe2 is greater than the hole mobility μh2 by about two digits, the exciton density ratios for different values of ΔE2 tend to be smaller than those in the results of the calculation experiment. However, it should be noted that the ratio of the number of excitons generated in the light-emitting layer 14 and bringing about degradation in organic semiconductor material in non-emission deactivation state to the total number of excitons generated in the light-emitting layer 14 is extremely small, being typically around 10⁻²⁰. Thus, it can be considered that longevity of the organic EL element 1 can be achieved as long as the parameter P2 is within the preferable value range determined through the simulation calculation, even if the electron mobility μe2 is greater than the hole mobility μh2 by about two digits.

### 4. PARAMETERS P1 AND P3

The inventors investigated a preferable value for parameter P3 by conducting a simulation calculation.

In this simulation calculation, the inventors set fixed values to ΔE1 and ΔE2, and calculated hole density distribution and recombination rate distribution in the film thickness direction of the organic EL element 1 by setting different values (i.e., 0 [eV], 0.05 [eV], 0.1 [eV], 0.15 [eV], 0.2 [eV], 0.47 [eV], and 0.9 [eV]) to ΔH. In this simulation calculation, the mobility ratio μh3/μh2 of the hole mobility μh3 in the electron transport layer 15 to the hole mobility μh2 in the light-emitting layer 14 was set to 12.

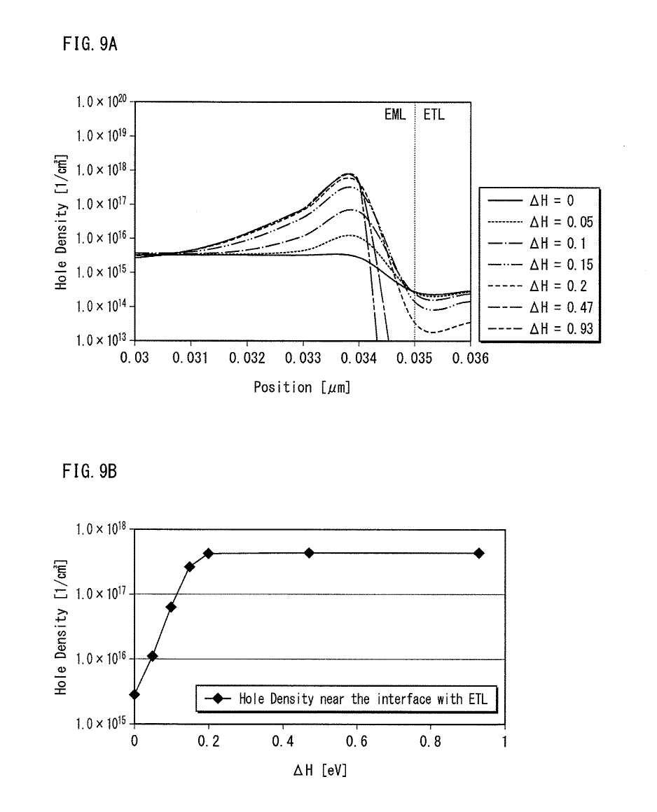

FIG. 9A is a graph showing hole density distributions near the interface between the light-emitting layer 14 and the electron transport layer 15 for the different values of the energy barrier ΔH in this simulation calculation. FIG. 9B is a graph showing the relationship between the energy barrier ΔH and the peak hole density in the light-emitting layer 14.

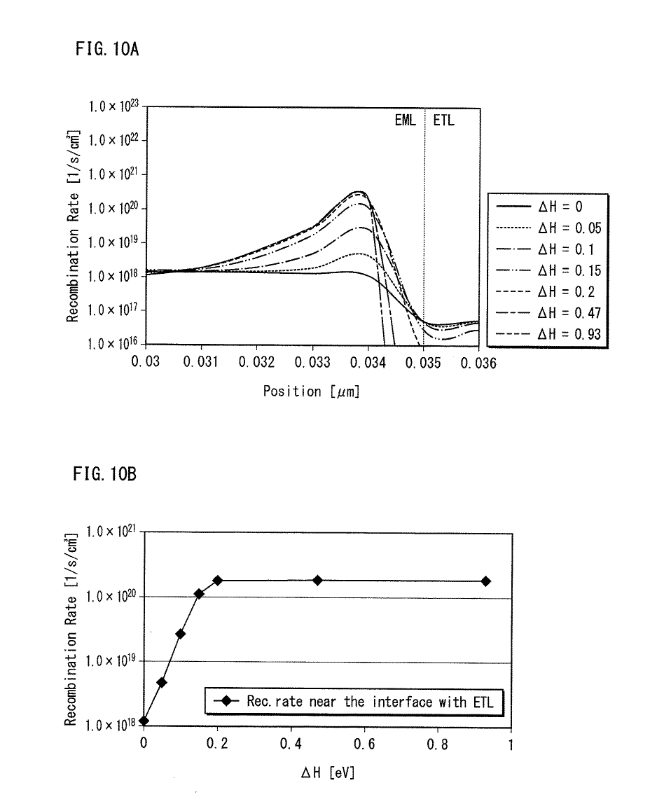

FIG. 10A is a graph showing recombination rates near the interface between the light-emitting layer 14 and the electron transport layer 15 for the different values of the energy barrier ΔH in the simulation calculation. FIG. 10B is a graph showing the relationship between the energy barrier ΔH and the peak recombination rate in the light-emitting layer 14.

As illustrated in FIG. 9A, a peak in hole density was observed in the light-emitting layer 14 near the interface with the electron transport layer 15 when ΔH was 0.05 [eV] or greater.

Further, as illustrated in FIG. 9B, saturation of the peak hole density was observed when ΔH was 0.2 [eV]. Meanwhile, the peak hole density was around one tenth of the saturation value when ΔH was 0.1 [eV].

A similar trend was observed with the recombination rate. That is, a peak in recombination rate was observed when ΔH was 0.05 [eV] or greater as illustrated in FIG. 10A, and saturation of the peak recombination rate was observed when ΔH was 0.2 [eV] as illustrated in FIG. 10B. Meanwhile, the peak recombination rate was around one tenth of the saturation value when ΔH was 0.1 [eV].

This shows that the energy barrier ΔH, due to serving as the injection barrier in hole injection from the light-emitting layer 14 to the electron transport layer 15, influences hole accumulation in the light-emitting layer near the interface with the electron transport layer 15 and thus brings about recombination near this interface. Accordingly, it can be considered that accumulation of holes at an amount corresponding to one tenth of the saturation value is preferable in order to cause recombination in the light-emitting layer near the interface with the electron transport layer 15.

Due to this, it can be expected that hole accumulation sufficient to bring about recombination can be achieved by setting ΔH to 0.1 [eV] or greater in this simulation calculation.

The value range of parameter P3 corresponding to this range of ΔH is 2.090×10⁻² or smaller according to Math 17, because the mobility ratio μh3/μh2 does not influence hole injection due to the hole mobility μh3 used in the simulation calculation being greater than the hole mobility Δh2. Accordingly, it can be concluded that it is preferable to set a value 2.090×10⁻² or smaller to the parameter P3.

Further, it can be considered that setting 0.2 [eV] to ΔH in the simulation calculation is preferable for achieving the saturation value of the peak hole density and thereby bringing about recombination. Meanwhile, setting a value greater than 0.2 [eV] to ΔH does not lead to further improvement of the recombination rate in the light-emitting layer 14 near the interface with the electron transport layer 15, while bringing about a further increase in driving voltage of the organic EL element 1 (typically, the greater the value set to ΔH, the greater the driving voltage of the organic EL element 1). This is because saturation of the peak hole density is already observed when ΔH=0.2 [eV]. Accordingly, it can be concluded that it is preferable to set a value no smaller than 0.1 [eV] and no greater than 0.2 [eV] to ΔH.

The value range of parameter P3 corresponding to this range of ΔH is 4.367×10⁻⁴ or greater and 2.090×10⁻² or smaller according to Math 17. Accordingly, it can be concluded that it is preferable to set a value 4.367×10⁻⁴ or greater and 2.090×10⁻² or smaller to the parameter P3.

Further, the above-described simulation calculation uses different values of ΔH to specify the condition that needs to be satisfied for holes having been transported through the light-emitting layer 14 to accumulate near the interface with the electron transport layer 15. Meanwhile, the same results (values) can be obtained by conducting a simulation calculation by setting various values to ΔE1 while setting fixed values to the other energy barriers. Due to this, the preferable value range of parameter P1 equals the preferable value range of parameter P3, which has been described above.

Specifically, it is preferable that a value 2.090×10⁻² or smaller be set to the parameter P1, and it is further preferable that a value 4.367×10⁻⁴ or greater and 2.090×10⁻² or smaller be set to the parameter P1.

### 5. Conclusion

As described up to this point, in the organic EL element 1 pertaining to this embodiment, electrons are accumulated in the light-emitting layer 14 near the interface with the hole transport layer 13, holes are accumulated in the light-emitting layer 14 near the interface with the electron transport layer 15, and carrier recombination occurs in the light-emitting layer 14 near these interfaces due to parameter P1 being set to 2.090×10⁻² or smaller, parameter P2 being set to 4.367×10⁻⁴ or smaller, and parameter P3 being set to 2.090×10⁻² or smaller. Accordingly, the crowding of excitons in the light-emitting layer 14 only near the interface with the hole transport layer 13 in the exciton density distribution of the light-emitting layer 14 is suppressed.

Due to this, the peak recombination rate in the light-emitting layer 14 in the organic light-emitting element 1 is lower than that in the light-emitting layer in a conventional organic EL element in which recombination occurs only near one of such interfaces, when the two organic EL elements are caused to emit light at the same luminance. As a result, local degradation of the light-emitting layer 14 is suppressed in the organic EL element 1, and thus, longevity of the organic EL element 1 is achieved.

Further, when parameter P2 is 3.984×10⁻⁹ or greater and 4.367×10⁻⁴ or smaller, the distribution of excitons in the light-emitting layer 14 is prevented from being greatly biased towards the interface with the electron transport layer 15, and thus, longevity of the organic EL element 1 is achieved.

Further, when parameter P2 is 1.295×1 or greater and 3.406×10⁻⁷ or smaller, in both the exciton density distribution and the recombination rate distribution, the peak value near the interface with the hole transport layer 13 and the peak value near the interface with the electron transport layer 15 become more similar to one another, and thus, further longevity of the organic EL element 1 is achieved.

Further, when parameter P1 is 4.367×10⁻⁴ or greater and 2.090×10⁻² or smaller, longevity of the organic EL element 1 is achieved without an excessive increase in driving voltage of the organic EL element 1.

Further, when parameter P3 is 4.367×10⁻⁴ or greater and 2.090×10⁻² or smaller, longevity of the organic EL element 1 is achieved without an excessive increase in driving voltage of the organic EL element 1.

The following describes how a HOMO energy level, a LUMO energy level, an electron mobility, and a hole mobility of an organic material can each be measured. Such measurement is necessary in selecting the first, second, and third organic semiconductors such that the parameters P1, P2, and P3 have values within the respective ranges described above.

A HOMO energy level of an organic material can be measured by conducting photoelectron spectroscopy, specific examples of which include X-ray photoelectron spectroscopy (XPS) and ultraviolet photoelectron spectroscopy (UPS). Photoelectron spectroscopy reveals the electron state of occupied energy levels at an organic semiconductor surface.

A LUMO energy level of an organic material can be measured by conducting inverse photoelectron spectroscopy (IPES). Photoelectron spectroscopy reveals the electron state of unoccupied energy levels at an organic semiconductor surface.

Electron mobility and hole mobility can be measured by conducting a time of flight (TOF) method or impedance spectroscopy. In particular, with the impedance spectroscopy method disclosed in “Determination of Drift Mobility and Localized-state Distribution in Organic Light-emitting Diodes by Impedance Spectroscopy” (Hiroyoshi NAITO, Journal of the Surface Science Society of Japan Vol. 33, No. 2, pp. 69-74, 2012), measurement of mobility can be conducted with respect to a functional element such as an OLED without using any mobility measurement device.

### 6. Modification 1

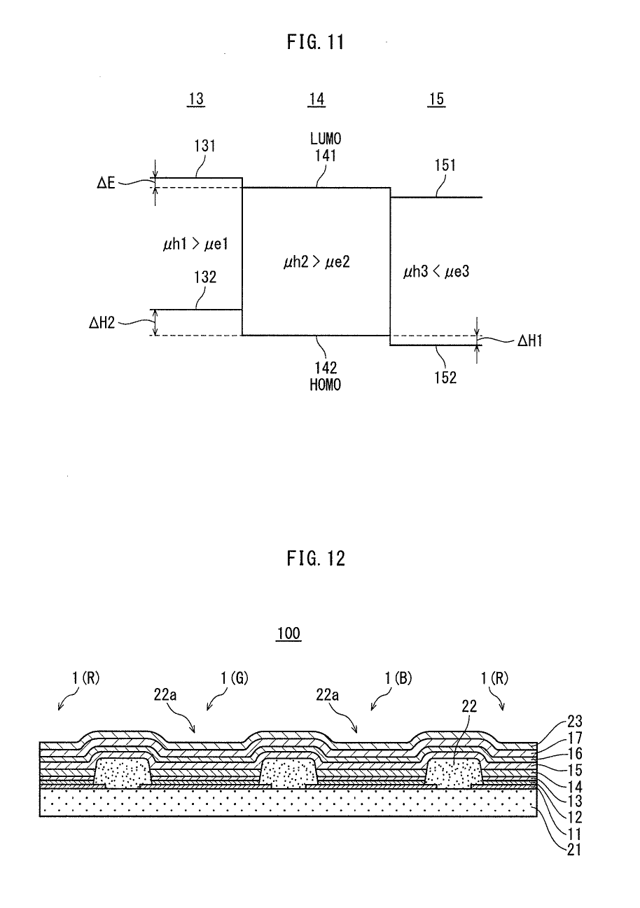

FIG. 11 is an energy band diagram illustrating the energy band structure in an organic EL element pertaining to modification 1. The organic EL element pertaining to modification 1 differs from the organic EL element illustrated in FIG. 2 in that the second organic semiconductor contained in the light-emitting layer 14 is a hole transport material. That is, as the second organic semiconductor, a known organic material that is a hole transport material can be used in modification 1. In particular, in modification 1, it is preferable that the material used for the second organic semiconductor be such that the ratio μe2/μh2 indicating the ratio of the electron mobility μe2 to the hole mobility μh2 has a value no greater than 0.5.

The organic EL element pertaining to modification 1 illustrated in FIG. 11 is similar to the organic EL element illustrated in FIG. 2 in aspects other than this. Further, the hole accumulation characteristic at the interface between the light-emitting layer 14 and the electron transport layer 15 in the organic EL element pertaining to modification 1 is equivalent to the electron accumulation characteristic at the interface between the light-emitting layer 14 and the hole transport layer 13 in the organic EL element illustrated in FIG. 2. Similarly, the hole accumulation characteristic at the interface between the hole transport layer 13 and the light-emitting layer 14 in the organic EL element pertaining to modification 1 is equivalent to the electron accumulation characteristic at the interface between the electron transport layer 15 and the light-emitting layer 14 in the organic EL element illustrated in FIG. 2. Further, the electron accumulation characteristic at the interface between the light-emitting layer 14 and the hole transport layer 13 in the organic EL element pertaining to modification 1 is equivalent to the hole accumulation characteristic at the interface between the light-emitting layer 14 and the electron transport layer 15 in the organic EL element illustrated in FIG. 2.

Specifically, in the organic EL element pertaining to modification 1, the organic materials that are used for the first, second, and third organic semiconductors are selected so that parameters P4, P5, and P6 have values within the respective ranges described later in the present disclosure. Specifically, parameter P4 is related to the injection of holes from the light-emitting layer 14 to the electron transport layer 15, parameter P5 is related to the injection of holes from the hole transport layer 13 to the light-emitting layer 14, and parameter P6 is related to the injection of electrons from the light-emitting layer 14 to the hole transport layer 13.

Specifically, it is preferable to set a value 2.090×10⁻² or smaller to parameters P4 and P6. It is further preferable to set a value 4.367×10⁻⁴ or greater and 2.090×10⁻² or smaller to parameters P4 and P6.

It is preferable to set a value 4.367×10⁻⁴ or smaller to parameter P5. It is further preferable to set a value 3.984×10⁻⁹ or greater and 4.367×10⁻⁴ or smaller to the parameter P5. It is even further preferable to set a value 1.295×10⁻⁷ or greater and 3.406×10⁻⁷ or smaller to parameter P5.

Further, when hole mobility μh3 is smaller than hole mobility μh2 and thus μh3/μh2 influences hole injection from the light-emitting layer 14 to the electron transport layer 15, the parameter P4 can be expressed by Math 18, using the energy barrier ΔH1, the hole mobility μh3 of the electron transport layer 15, and the hole mobility μh2 of the light-emitting layer 14.

$$P 4 = \frac{μ h 3}{μ h 2} \times exp ( - 38.681731 \times Δ H 1 ) \qquad ( Math 18 )$$

Meanwhile, when hole mobility Δh3 is greater than or equal to hole mobility μh2 and thus μh3/μh2 does not influence hole injection from the light-emitting layer 14 to the electron transport layer 15, the parameter P4 can be expressed by Math 19, using the energy barrier ΔH1.

P4=exp(−38.681731×ΔH1) (Math 19)

Further, when hole mobility μh2 is smaller than hole mobility μh1 and thus μh2/μh1 influences hole injection from the hole transport layer 13 to the light-emitting layer 14, the parameter P5 can be expressed by Math 20, using the energy barrier ΔH2, the hole mobility μh1 of the hole transport layer 13, and the hole mobility μh2 of the light-emitting layer 14.

$$P 5 = \frac{μ h 2}{μ h 1} \times exp ( - 38.681731 \times Δ H 2 ) \qquad ( Math 20 )$$

Meanwhile, when hole mobility μh2 is greater than or equal to hole mobility μh1 and thus μh2/μh1 does not influence hole injection from the hole transport layer 13 to the light-emitting layer 14, the parameter P5 can be expressed by Math 21, using the energy barrier ΔH2.

P5=exp(−38.681731λΔH2) (Math 21)

Further, when electron mobility μe1 is smaller than electron mobility μe2 and thus μe1/μe2 influences electron injection from the light-emitting layer 14 to the hole transport layer 13, the parameter P6 can be expressed by Math 22, using the energy barrier ΔE, the electron mobility μe1 of the hole transport layer 13, and the electron mobility μe2 of the light-emitting layer 14.

$$P 6 = \frac{μ e 1}{μ e 2} \times exp ( - 38.681731 \times Δ E ) \qquad ( Math 22 )$$

Meanwhile, when electron mobility μe1 is greater than or equal to electron mobility μe2 and thus μe1/μe2 does not influence electron injection from the light-emitting layer 14 to the hole transport layer 13, the parameter P6 can be expressed by Math 23, using the energy barrier ΔE.

P6=exp(−38.681731×ΔE) (Math 23)

As described up to this point, in the organic EL element pertaining to modification 1, electrons are accumulated in the light-emitting layer 14 near the interface with the hole transport layer 13, holes are accumulated in the light-emitting layer 14 near the interface with the electron transport layer 15, and carrier recombination occurs in the light-emitting layer 14 near these interfaces due to parameter P4 being set to 2.090×10⁻² or smaller, parameter P5 being set to 4.367×10⁻⁴ or smaller, and parameter P6 being set to 2.090×10⁻² or smaller. Accordingly, the crowding of excitons in the light-emitting layer 14 only near the interface with the electron transport layer 15 in the exciton density distribution of the light-emitting layer 14 is suppressed, although the second organic semiconductor is a hole transport material.

Due to this, the peak recombination rate in the light-emitting layer 14 in the organic EL element pertaining to modification 1 is lower than that in the light-emitting layer in a conventional organic EL element in which recombination occurs only near one of such interfaces, when the two organic EL elements are caused to emit light at the same luminance. As a result, local degradation of the light-emitting layer 14 is suppressed in the organic EL element pertaining to modification 1, and thus, longevity of the organic EL element pertaining to modification 1 is achieved.

Further, when parameter P5 is 3.984×10⁻⁹ or greater and 4.367×10⁻⁴ or smaller, the distribution of excitons in the light-emitting layer 14 is prevented from being greatly biased towards the interface with the hole transport layer 13, and thus, longevity of the organic EL element pertaining to modification 1 is achieved.

Further, when parameter P5 is 1.295×10⁻² or greater and 3.406×10⁻⁷ or smaller, in the exciton density distribution, the peak value near the interface with the hole transport layer 13 and the peak value near the interface with the electron transport layer 15 become more similar to one another, and thus, further longevity of the organic EL element pertaining to modification 1 is achieved.

Further, when parameter P4 is 4.367×10⁻⁴ or greater and 2.090×10⁻² or smaller, longevity of the organic EL element pertaining to modification 1 is achieved without an excessive increase in driving voltage of the organic EL element pertaining to modification 1.

Further, when parameter P6 is 4.367×10⁻⁴ or greater and 2.090×10⁻² or smaller, longevity of the organic EL element pertaining to modification 1 is achieved without an excessive increase in driving voltage of the organic EL element pertaining to modification 1.

### 7. Modification 2

Modification 2 differs from the embodiment and modification 1 in that the electron mobility and the hole mobility of the second organic semiconductor contained in the light-emitting layer are similar. In the present disclosure, electron mobility and hole mobility are considered as being similar when the ratio μe2/μh2 indicating the ratio of the electron mobility μe2 to the hole mobility μh2 in the second organic semiconductor has a value no smaller than 0.5 and no greater than 2.

That is, as the second organic semiconductor, a known organic material whose electron mobility and hole mobility are similar can be used in modification 2.

The organic EL element pertaining to modification 2 is similar to the organic EL element illustrated in FIG. 2 in aspects other than this. Further, the electron accumulation characteristic at the interface between the light-emitting layer 14 and the hole transport layer 13 in the organic EL element pertaining to modification 2 is equivalent to the electron accumulation characteristic at the interface between the light-emitting layer 14 and the hole transport layer 13 in the organic EL element illustrated in FIG. 2. Similarly, the hole accumulation characteristic at the interface between the light-emitting layer 14 and the electron transport layer 15 in the organic EL element pertaining to modification 2 is equivalent to the hole accumulation characteristic at the interface between the light-emitting layer 14 and the electron transport layer 15 in the organic EL element illustrated in FIG. 2.

Specifically, in the organic EL element pertaining to modification 2, the organic materials that are used for the first, second, and third organic semiconductors are selected so that parameters P7 and P8 have values within the respective ranges described later in the present disclosure. Specifically, parameter P7 is related to the injection of electrons from the light-emitting layer 14 to the hole transport layer 13, and parameter P8 is related to the injection of holes from the light-emitting layer 14 to the electron transport layer 15.

Specifically, it is preferable to set a value 2.090×10⁻² or smaller to parameter P7 and parameter P8. It is further preferable to set a value 4.367×10⁻⁴ or greater and 2.090×10⁻² or smaller to parameters P7 and P8.

Here, when electron mobility μe1 is smaller than electron mobility μe2 and thus μe1/μe2 influences electron injection from the light-emitting layer 14 to the hole transport layer 13, the parameter P7 can be expressed by Math 24, using the energy barrier ΔE (i.e., the difference between the LUMO energy level 131 of the hole transport layer 13 and the LUMO energy level 141 of the light-emitting layer 14), the electron mobility μe1 of the hole transport layer 13, and the electron mobility μe2 of the light-emitting layer 14.

$$P 7 = \frac{μ e 1}{μ e 2} \times exp ( - 38.681731 \times Δ E ) \qquad ( Math 24 )$$

Meanwhile, when electron mobility μe1 is greater than or equal to electron mobility μe2 and thus μe1/μe2 does not influence electron injection from the light-emitting layer 14 to the hole transport layer 13, the parameter P7 can be expressed by Math 25, using the energy barrier ΔE.

P7−exp(−38.681731×ΔE) (Math 25)

Meanwhile, when hole mobility μh3 is smaller than hole mobility μh2 and thus μh3/μh2 influences hole injection from the light-emitting layer 14 to the electron transport layer 15, the parameter P8 can be expressed by Math 26, using the energy barrier ΔH (i.e., the difference between the HOMO energy level 142 of the light-emitting layer 14 and the HOMO energy level 152 of the electron transport layer 15), the hole mobility Δh3 of the electron transport layer 15, and the hole mobility μh2 of the light-emitting layer 14.

$$P 8 = \frac{μ h 3}{μ h 2} \times exp ( - 38.681731 \times Δ H ) \qquad ( Math 26 )$$

Meanwhile, when hole mobility μh3 is greater than or equal to hole mobility μh2 and thus μh3/μh2 does not influence hole injection from the light-emitting layer 14 to the electron transport layer 15, the parameter P8 can be expressed by Math 27, using the energy barrier ΔH.

P8=exp(−38.681731×ΔH) (Math 27)

As described up to this point, in the organic EL element pertaining to modification 2, electrons are accumulated in the light-emitting layer 14 near the interface with the hole transport layer 13, holes are accumulated in the light-emitting layer 14 near the interface with the electron transport layer 15, and carrier recombination occurs in the light-emitting layer 14 near these interfaces due to parameter P7 being set to 2.090×10⁻² or smaller and parameter P8 being set to 2.090×10⁻² or smaller.

Due to this, the peak recombination rate in the light-emitting layer 14 in the organic EL element pertaining to modification 2 is lower than that in the light-emitting layer in a conventional organic EL element in which recombination occurs only near one of such interfaces, when the two organic EL elements are caused to emit light at the same luminance. As a result, local degradation of the light-emitting layer 14 is suppressed in the organic EL element pertaining to modification 2, and thus, longevity of the organic EL element pertaining to modification 2 is achieved.

Further, when parameter P7 is 4.367×10⁻⁴ or greater and 2.090×10⁻² or smaller, longevity of the organic EL element pertaining to modification 2 is achieved without an excessive increase in driving voltage of the organic EL element pertaining to modification 2.

Further, when parameter P8 is 4.367×10⁻⁴ or greater and 2.090×10⁻² or smaller, longevity of the organic EL element pertaining to modification 2 is achieved without an excessive increase in driving voltage of the organic EL element pertaining to modification 2.

### Embodiment 2

Embodiment 2 describes an organic EL display panel 100 that includes a plurality of the organic EL elements 1 described in embodiment 1 arrayed on a substrate.

### [1. Organic EL Display Panel Structure]

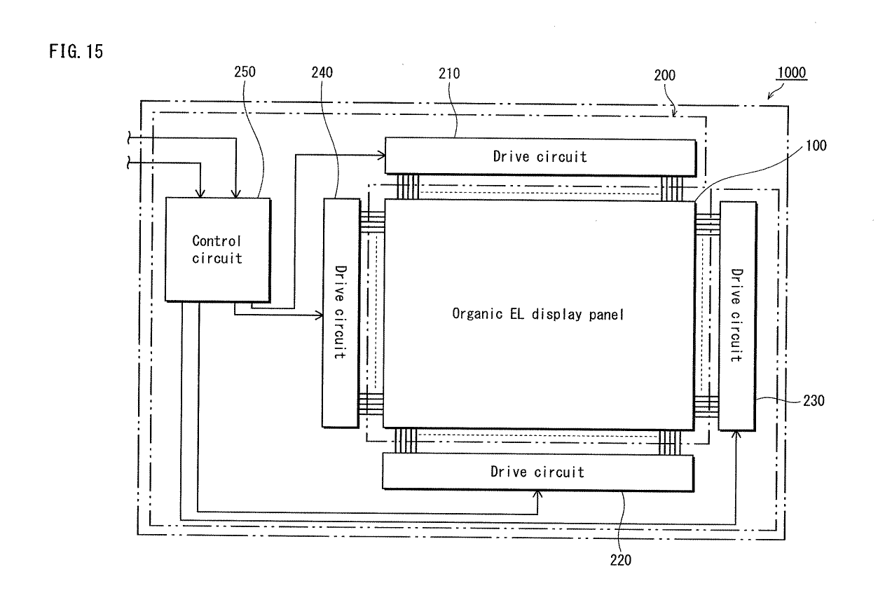

FIG. 12 is a cross-sectional view illustrating a part of the organic EL display panel 100 pertaining to embodiment 2 (refer to FIG. 15). The organic EL display panel 100 includes a plurality of pixels, each of which includes an organic EL element 1(R) that emits red light, an organic EL element 1(G) that emits green light, and an organic EL element 1(B) that emits blue light. FIG. 12 illustrates a cross-section around one organic EL element 1(B).

The organic EL elements 1 in the organic EL display panel are top-emission-type elements and emit light in a forward direction (the upward direction in FIG. 12).

Because the organic EL elements 1(R), 1(G), and 1(B) have substantially similar structures, they are collectively referred to and described as organic EL elements 1 in the following.

As illustrated in FIG. 12, each organic EL element 1 includes a TFT substrate 21, an anode 11, a bank layer 22, a hole injection layer 12, a hole transport layer 13, a light-emitting layer 14, an electron transport layer 15, an electron injection layer 16, a cathode 17, and a sealing layer 23. Note that among such layers, the TFT substrate 21, the electron transport layer 15, the electron injection layer 16, the cathode 17, and the sealing layer 23 each are not formed for each sub-pixel, and each instead are formed to cover all of the organic EL elements 1 of the organic EL display panel 100.

In the following, description related to the structure of the organic EL elements 1 already provided in embodiment 1 is not repeated, and description is provided mainly focusing on the materials for the organic EL elements 1.

The TFT substrate 21 includes an electrically-insulative base, a thin film transistor (TFT) layer, and an interlayer electrically-insulative layer. The TFT layer has a drive circuit for each sub-pixel. The base is a substrate formed by using, for example, a glass material. The glass material may, for example, non-alkali glass, soda glass, nonfluorescent glass, phosphate glass, borate glass, or quartz glass. The interlayer electrically-insulative layer is formed by using a resin material, and covers level differences present on the top surface of the TFT layer. For example, the interlayer electrically-insulative layer may be formed by using a positive photosensitive material. The photosensitive material may, for example, be acrylic resin, polyimide resin, siloxane resin, or phenolic resin.

Further, although not illustrated in the cross-sectional view of FIG. 12, the interlayer electrically-insulative layer of the TFT substrate 21 has contact holes, one for each sub-pixel.

The anodes 11 are formed on the interlayer electrically-insulative layer of the TFT substrate 21, one for each sub-pixel, and are electrically connected to the TFT layer via the contact holes. The anodes 11 each include a metal layer formed by using a light-reflective metal material. Examples of light-reflective metal materials include silver (Ag), aluminum (Al), aluminum alloys, molybdenum (Mo), APC (alloy of silver, palladium, and copper), ARA (alloy of silver, rubidium, and gold), MoCr (alloy of molybdenum and chromium), MoW (alloy of molybdenum and tungsten), and NiCr (alloy of nickel and chromium). Further, while each anode 11 may be formed solely from such a metal layer, each anode 11 may alternatively have a multi-layer structure with a layer formed by using a metal oxide such as ITO or IZO stacked on the metal layer.

The bank layer 22 is formed on the anodes 11, exposing an area of the top surface of each anode 11 and covering an area of the top surface of each anode 11 around the exposed area. The area of the top surface of each anode 11 that is not covered by the bank layer 22 (referred to in the following as an opening) corresponds to one sub-pixel. That is, the bank layer 22 has openings 22a, one for each sub-pixel.

In each of the openings 22a above the anodes 11, the hole injection layer 12, the hole transport layer 13, and the light-emitting layer 14 are formed in this order one on top of another.

The hole injection layer 12 is formed by using, for example, an oxide of a material such as Ag, Mo, chromium (Cr), vanadium (V), tungsten (W), nickel (Ni), and iridium (Ir), or an electrically-conductive polymer material such as polyethylenedioxythiophene (PEDOT; mixture of polythiophene and polystyrene sulfonic acid).

The hole transport layer 13 contains the first organic semiconductor. For example, as the first organic semiconductor, a high molecular compound such as polyfluorene or a derivative thereof or polyarylamine or a derivative thereof may be used.

The light-emitting layer 14 contains the second organic semiconductor. For example, as the second organic semiconductor, a fluorescent material such as: an oxinoid compound; a perylene compound; a coumarin compound; an azacoumarin compound; an oxazole compound; an oxadiazole compound; a perinone compound; a pyrrolo-pyrrole compound; a naphthalene compound; an anthracene compound; a fluorene compound; a fluoranthene compound; a tetracene compound; a pyrene compound; a coronene compound; a quinolone compound; an azaquinolone compound; a pyrazoline derivative and a pyrazolone derivative; a rhodamine compound; a chrysene compound; a phenanthrene compound; a cyclopentadiene compound; a stilbene compound; a diphenylquinone compound; a styryl compound; a butadiene compound; a dicyanomethylene pyran compound; a dicyanomethylene thiopyran compound; a fluorescein compound; a pyrylium compound; a thiapyrylium compound; a selenapyrylium compound; a telluropyrylium compound; an aromatic aldadiene compound; an oligophenylene compound; a thioxanthene compound; a cyanine compound; an acridine compound; a metal complex of an 8-hydroxyquinoline compound; a metal complex of a 2-bipyridine compound; a complex of a Schiff base and a group III metal; a metal complex of oxine; and rare earth metal complex, or a metal complex emitting phosphorescence, such as tris(2-phenylpyridine) iridium, may be used.

The electron transport layer 15 is formed, for example, by doping the third organic semiconductor, which is an electron transport material, with a dopant metal selected from alkali metals or alkaline earth metals. For example, as the third organic semiconductor, a π-electron system low molecular organic material such as an oxydiazole derivative (OXD), a triazole derivative (TAZ), or a phenanthroline derivative (BCP, Bphen) may be used.

The electron injection layer 16 is a functional layer containing a metal or a metal oxide. As the material of the electron injection layer 16, an electron-injecting material such as lithium fluoride (LiF), sodium fluoride (NaF), quinolinol lithium complex (Liq), Ba, or Ag may be selected.

In this embodiment, the bank layer 22 covers portions of the TFT substrate 21 where the anodes 11 are not formed. That is, wherever the anodes 11 are not formed, the bottom surface of the bank layer 22 is in contact with the top surface of the TFT substrate 21.

The bank layer 22 is formed, for example, by using an electrically-insulative material such as, acrylic resin, polyimide resin, novolac resin, or phenolic resin. The bank layer 22 functions as a structure preventing applied ink from overflowing when forming the light-emitting layer 14 through ink application, and functions as a structure for mounting a vapor deposition mask when forming the light-emitting layer 14 through vapor deposition. In this embodiment, the bank layer 22 is formed by using a resin material that is, for example, a positive photosensitive material. Examples of such photosensitive materials include acrylic resin, polyimide resin, siloxane resin, and phenolic resin. In this embodiment, phenolic resin is used.

The cathode 17 covers all sub-pixels of the display panel 100. The cathode 17 includes at least one of a metal layer formed by using a metal material and a metal oxide layer formed by using a metal oxide. The metal layer included in the cathode 17 is thin, having a thickness set to around 1 nm to 50 nm, and thus is light-transmissive. That is, while metal material is typically light-reflective, light-transmissivity of the metal layer can be ensured by providing the metal layer with a thickness of 50 nm or smaller. Accordingly, while some light from the light-emitting layers 14 is reflected at the cathode 17, the rest of the light passes through the cathode 17.

Examples of the metal material for forming the metal layer included in the cathode 17 include Ag, an Ag alloy containing Ag as the main component, Al, or an Al alloy containing Al as the main component. Examples of Ag alloys include magnesium silver alloy (MgAg) and indium silver alloy. Ag are preferable for their basically low resistivity, and Ag alloys are preferable in that they have excellent heat and corrosion resistance and can maintain good electrical conductivity over a long period of time. Examples of Al alloys include magnesium aluminum alloy (MgAl) and lithium aluminum alloy (LiAl). Examples of other alloys usable for forming the metal layer include lithium magnesium alloy and lithium indium alloy.

The metal layer included in the cathode 17 may have a single-layer structure composed of for example only an Ag layer or a MgAg alloy layer, or may have a multi-layer structure composed of an Mg layer and an Ag layer (Mg/Ag) or composed of an MgAg alloy layer and an Ag layer (MgAg/Ag).

Alternatively, the cathode 17 may have a single-layer structure composed of only a metal layer or a metal oxide layer, or may have a multi-layer structure including a metal layer and a metal oxide layer composed of a metal oxide such as ITO or IZO layered on the metal layer.

On the cathode 17, which covers all sub-pixels of the display panel 100, is disposed the sealing layer 23, which is disposed to suppress degradation of the light-emitting layers 14 due to contact with moisture, oxygen, etc. Because the organic EL display panel 100 is a top-emission type display panel, a light transmissive material such as silicon nitride (SiN) or silicon oxynitride (SiON) is selected for example as the material of the sealing layer 23.

Although not illustrated in FIG. 12, a color filter, an upper substrate, and/or the like may be adhered on top of the sealing layer 23 via a sealing resin. Adhesion of the upper substrate onto the sealing layer 23 achieves protection of the hole transport layers 13, the light-emitting layers 14, and the electron transport layer 15 from moisture, air, etc.

### [2. Manufacturing Method of Organic EL Element]

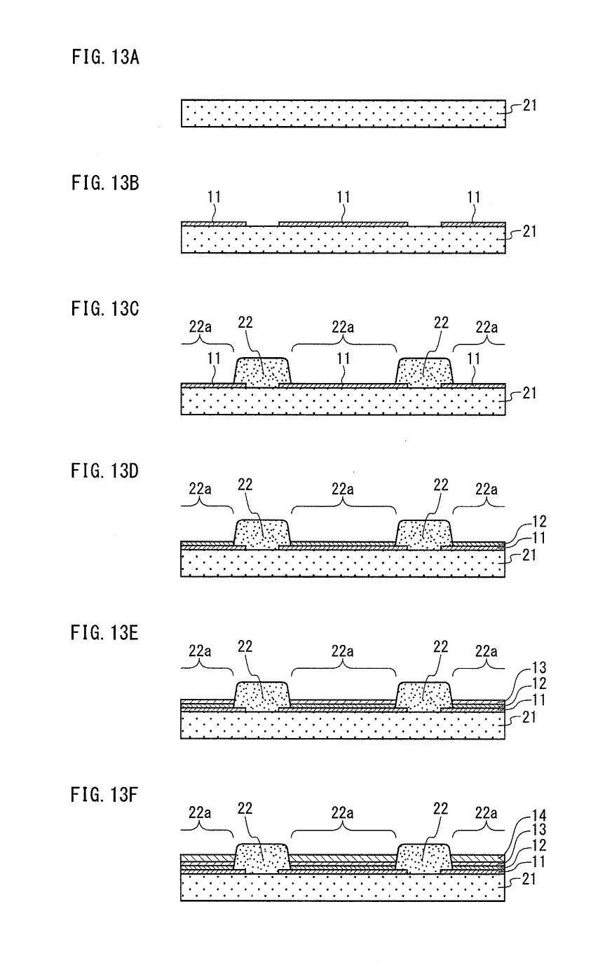

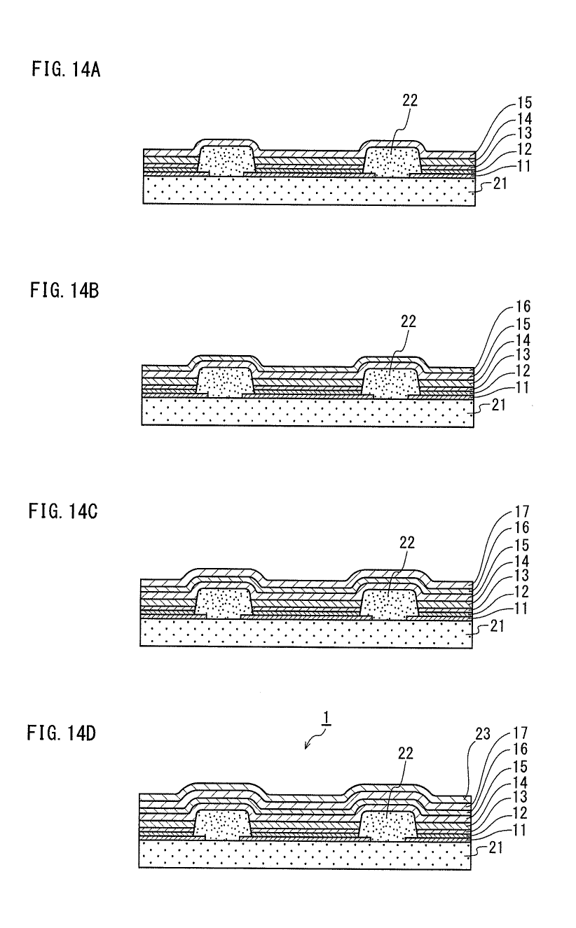

The following describes a manufacturing method of the organic EL elements 1, with reference to FIGS. 13A through 13F and FIGS. 14 through 14D. FIGS. 13A through 13F and FIGS. 14 through 14D are cross-sectional views schematically showing the manufacturing process of the organic EL elements 1.

Initially, as illustrated in FIG. 13A, the TFT substrate 21 is prepared. Subsequently, for each sub-pixel, a film having a thickness within the range from 50 nm to 500 nm is formed through vacuum deposition or sputtering of a metal material, whereby the anodes 11 are formed as illustrated in FIG. 13B.

Subsequently, on the anodes 11, bank layer resin that is the material of the bank layer 22 is uniformly applied to form a bank material layer. For the bank layer resin, for example, phenolic resin, which is a positive photosensitive material, is used. The forming of the bank layer 22 is completed by forming a pattern in the shape of the bank layer 22 by exposing the bank material layer to light and performing developing, and then performing baking (FIG. 13C). This baking is performed, for example, at a temperature no lower than 150° C. and no higher than 210° C. for 60 minutes. The bank layer 22 so formed defines the openings 22a, which are regions in which the light-emitting layers 14 are formed.

In the procedure of forming the bank layer 22, surface treatment using a predetermined alkaline solution, water, an organic solvent, or similar may be performed, and plasma treatment of a surface of the bank layer 22 may be performed, for example. Surface treatment of the bank layer 22 is performed for the purposes of, for example, adjusting the contact angle with respect to ink to be applied to the openings 22a and imparting liquid repellency to the surface of the bank layer 22.

Subsequently, through vapor deposition using a mask or inkjet application, material of the hole injection layers 12 is deposited and baking is performed to form the hole injection layers 12 as illustrated in FIG. 13D.

Subsequently, ink containing the material of the hole transport layers 13 is applied to the openings 22a defined by the bank layer 22, and baking (drying) is performed to form the hole transport layers 13 as illustrated in FIG. 13E.

Similarly, ink containing the material of the light-emitting layers 14 is applied and baking (drying) is performed to form the light-emitting layers 14 as illustrated in FIG. 13F.

Subsequently, as illustrated in FIG. 14A, on the light-emitting layers 14, the electron transport layer 15 is formed to have a thickness within the range from 10 nm to 100 nm through vacuum deposition or similar. The electron transport layer 15 is formed to also cover the bank layer 22. Subsequently, as illustrated in FIG. 14B, on the electron transport layer 15, the electron injection layer 16 is formed through vacuum deposition or similar.

Subsequently, as illustrated in FIG. 14C, on the electron injection layer 16, the cathode 17 is formed through vacuum deposition, sputtering, or similar, of a metal material.

Subsequently, on the cathode 17, the sealing layer 23 is formed through sputtering, CVD, or similar, of a light-transmissive material such as SiN or SiON, as illustrated in FIG. 14D.

Through the procedures described above, the organic EL elements 1 are completed, and the organic EL display panel 100, which includes a plurality of the organic EL elements 1 is also thereby completed. Note that a color filter, an upper substrate, and/or the like may be adhered onto the sealing layer 23.

### [3. Overall Structure of Organic EL Display Device]

FIG. 15 is a schematic block diagram illustrating the structure of an organic EL display device 1000. As illustrated in FIG. 15, the organic EL display device 1000 includes the organic EL display panel 100 and a drive controller 200 connected thereto. The driver controller 200 includes four drive circuits 210, 220, 230, 240 and a control circuit 250.

Note that the actual organic EL display device 1000 need not have the depicted example arrangement of the driver controller 200 relative to the organic EL display panel 100.

### Other Modifications

Up to this point, description is provided of embodiments 1 and 2. However, the present invention is not limited to these embodiments, and for example the following modifications can be made.

(1) In each embodiment, an organic EL element 1 includes the hole injection layer 12 and the electron injection layer 16. However, the present application is similarly implementable with an organic EL element without one or more of these two layers.

(2) The conditions regarding the ranges of film thickness in embodiment 2 need not be satisfied over the entirety of a sub-pixel defined by an opening 22a, as long as the conditions are satisfied at at least a part of the sub-pixel (e.g., at a center part of a sub-pixel).

(3) In embodiment 2, the base of the organic EL element 1 is described as containing glass as an electrically-insulative material, but this is just an example. As the electrically-insulative material for the base, a resin or a ceramic may be used, for example. One example of a ceramic usable for the base is alumina. Examples of resin usable for the base include an electrically-insulative material such as polyimide resin, acrylic resin, styrene resin, polycarbonate resin, epoxy resin, polyethersulfone, polyethylene, polyester, and silicone resin. When resin is used for the base, organic EL elements having flexibility can be achieved.

(4) Embodiment 2 describes a top-emission type structure in which the anodes 11 are formed by using light-reflective material and the cathode 17 is formed by using light-transmissive material. However, the present invention is implementable with a bottom-emission type structure in which the anodes 11 are formed by using light-transmissive material and the cathode 17 is formed by using light-reflective material.

(5) In embodiment 2, the hole transport layer 13 and the light-emitting layer 14 are formed through ink application, but this is just an example. For example, an organic EL element 1 may be formed by forming at least one of the hole transport layer 13 and the light-emitting layer 14 through vapor deposition.

The organic EL element pertaining to the present invention is useful in various display devices, televisions, displays for portable electronic devices, and illuminations, for home, public, or business use.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

What is claimed is:

1. An organic electroluminescence (EL) element comprising:
an anode;
a hole transport layer above the anode, the hole transport layer containing a first organic semiconductor;
a light-emitting layer on the hole transport layer, the light-emitting layer containing a second organic semiconductor;
an electron transport layer on the light-emitting layer, the electron transport layer containing a third organic semiconductor; and
a cathode above the electron transport layer, wherein
the first organic semiconductor, the second organic semiconductor, and the third organic semiconductor each have a highest occupied molecular orbital (HOMO) and a lowest unoccupied molecular orbital (LUMO),
the second organic semiconductor has higher electron mobility than hole mobility,
ΔE1 denoting a difference [eV] between a LUMO energy level of the first organic semiconductor and a LUMO energy level of the second organic semiconductor, μe1 denoting an electron mobility of the first organic semiconductor, and μe2 denoting an electron mobility of the second organic semiconductor
$$s atisfy$$
$$\frac{μ e 1}{μ e 2} \times exp ( - Δ E 1 \times 38.681731 ) \leq 2.090 \times {10}^{- 2}$$
$$when μ e 1 < μ e 2 , and$$
$$satisfy$$
$$exp ( - Δ E 1 \times 38.681731 ) \leq 2.090 \times {10}^{- 2}$$
$$when μ e 1 < μ e 2 ,$$
ΔE2 denoting a difference [eV] between the LUMO energy level of the second organic semiconductor and a LUMO energy level of the third organic semiconductor, μe2, and μe3 denoting an electron mobility of the third organic semiconductor
$$satisfy$$
$$\frac{μ e 2}{μ e 3} \times exp ( - Δ E 2 \times 38.681731 ) \leq 4.367 \times {10}^{- 4}$$
$$when μ e 2 < μ e 3 , and$$
$$satisfy$$
$$exp ( - Δ E 2 \times 38.681731 ) \leq 4.367 \times {10}^{- 4}$$
when μe2≧μe3, and
ΔH denoting a difference [eV] between a HOMO energy level of the second organic semiconductor and a HOMO energy level of the third organic semiconductor, μh2 denoting a hole mobility of the second organic semiconductor, and μh3 denoting a hole mobility of the third organic semiconductor
$$satisfy$$
$$\frac{μ h 3}{μ h 2} \times exp ( - Δ H \times 38.681731 ) \leq 2.090 \times {10}^{- 2}$$
$$when μ h 3 < μ h 2 , and$$
$$satisfy$$
$$exp ( - Δ I I \times 38.681731 ) \leq 2.090 \times {10}^{- 2}$$
$$when μ h 3 \geq μ h 2.$$

2. The organic EL element of claim 1, wherein
$$Δ E 2 , μ e 2 , and μ e 3$$
$$satisfy$$
$$3.984 \times {10}^{- 9} \leq \frac{μ e 2}{μ e 3} \times exp ( - Δ E 2 \times 38.681731 ) \leq 4.367 \times {10}^{- 4}$$
$$when μ e 2 < μ e 3 , and$$
$$satisfy$$
$$3.984 \times {10}^{- 9} \leq exp ( - Δ E 2 \times 38.681731 ) \leq 4.367 \times {10}^{- 4}$$
$$when μ e 2 < μ e 3.$$

3. The organic EL element of claim 2, wherein
$$Δ E 2 , μ e 2 , and μ e 3$$
$$satisfy$$
$$1.295 \times {10}^{- 7} \leq \frac{μ e 2}{μ e 3} \times exp ( - Δ E 2 \times 38.681731 ) \leq 3.406 \times {10}^{- 7}$$
$$when μ e 2 < μ e 3 , and$$
$$satisfy$$
$$1.295 \times {10}^{- 7} \leq exp ( - Δ E 2 \times 38.681731 ) \leq 3.406 \times {10}^{- 7}$$
$$when μ e 2 < μ e 3.$$

4. The organic EL element of claim 1, wherein
$$Δ E 1 , μ e 1 , and μ e 2$$
$$satisfy$$
$$4.367 \times {10}^{- 4} \leq \frac{μ e 1}{μ e 2} \times exp ( - Δ E 1 \times 38.681731 ) \leq 2.090 \times {10}^{- 2}$$
$$when μ e 1 < μ e 2 , and$$
$$satisfy$$
$$4.367 \times {10}^{- 4} \leq exp ( - Δ E 1 \times 38.681731 ) \leq 2.090 \times {10}^{- 2}$$
$$when μ e 1 \geq μ e 2.$$

5. The organic EL element of claim 1, wherein
$$Δ H , μ h 2 , and μ h 3$$
$$satisfy$$
$$4.367 \times {10}^{- 4} \leq \frac{μ h 3}{μ h 2} \times exp ( - Δ H \times 38.681731 ) \leq 2.090 \times {10}^{- 2}$$
$$when μh 3 < μ h 2 , and$$
$$satisfy$$
$$4.367 \times {10}^{- 4} \leq exp ( - Δ H \times 38.681731 ) \leq 2.090 \times {10}^{- 2}$$
$$when μ h 3 \geq μ h 2.$$

6. An organic electroluminescence (EL) element comprising:
an anode;
a hole transport layer above the anode, the hole transport layer containing a first organic semiconductor;
a light-emitting layer on the hole transport layer, the light-emitting layer containing a second organic semiconductor;
an electron transport layer on the light-emitting layer, the electron transport layer containing a third organic semiconductor; and
a cathode above the electron transport layer, wherein
the first organic semiconductor, the second organic semiconductor, and the third organic semiconductor each have a highest occupied molecular orbital (HOMO) and a lowest unoccupied molecular orbital (LUMO),
the second organic semiconductor has higher hole mobility than electron mobility,
ΔH1 denoting a difference [eV] between a HOMO energy level of the third organic semiconductor and a HOMO energy level of the second organic semiconductor, μh3 denoting a hole mobility of the third organic semiconductor, and μh2 denoting a hole mobility of the second organic semiconductor
$$satisfy$$
$$\frac{μ h 3}{μ h 2} \times exp ( - Δ H 1 \times 38.681731 \leq 2.090 \times {10}^{- 2} \\ when μ h 3 < μ h 2 , and \\ satisfy \\ exp ( Δ H 1 \times 38.681731 ) \leq 2.090 \times {10}^{- 2} \\ when μ h 3 < μ h 2 ,$$
ΔH2 denoting a difference [eV] between the HOMO energy level of the second organic semiconductor and a HOMO energy level of the first organic semiconductor, μh2, and μh1 denoting a hole mobility of the first organic semiconductor
$$satisfy$$
$$\frac{μ h 2}{μ h 1} \times exp ( - Δ H 2 \times 38.681731 ) \leq 4.367 \times {10}^{- 4}$$
$$when μ h 2 < μ h 1 , and$$
$$satisfy$$
$$exp ( - Δ H 2 \times 38.681731 ) \leq 4.367 \times {10}^{- 4}$$
$$when μ h 2 \geq μ h 1 , and$$
ΔE denoting a difference [eV] between a LUMO energy level of the second organic semiconductor and a LUMO energy level of the first organic semiconductor, μe2 denoting an electron mobility of the second organic semiconductor, and μe1 denoting an electron mobility of the first organic semiconductor
$$satisfy$$
$$\frac{μ e 2}{μ e 1} \times exp ( - Δ E \times 38.681731 ) \leq 2.090 \times {10}^{- 2}$$
$$when μ e 1 < μ e 2 , and$$
$$satisfy$$
$$exp ( - Δ E \times 38.681731 ) \leq 2.090 \times {10}^{- 2}$$
$$when μ e 1 \geq μ e 2.$$

7. The organic EL element of claim 6, wherein
$$Δ H 2 , μ h 2 , and μ h 1$$
$$satisfy$$
$$3.984 \times {10}^{- 9} \leq \frac{μ h 2}{μ h 1} \times exp ( - Δ H 2 \times 38.681731 ) \leq 4.367 \times {10}^{- 4}$$
$$when μh 2 < μ h 1 , and$$
$$satisfy$$
$$3.984 \times {10}^{- 9} \leq exp ( - Δ H 2 \times 38.681731 ) \leq 4.367 \times {10}^{- 4}$$
$$when μ h 2 \geq μ h 1.$$

8. The organic EL element of claim 7, wherein
$$Δ H 2 , μ h 2 , and μ h 1$$
$$satisfy$$
$$1.295 \times {10}^{- 7} \leq \frac{μ h 2}{μ h 1} \times exp ( - Δ H 2 \times 38.681731 ) \leq 3.406 \times {10}^{- 7}$$
$$when μh 2 < μ h 1 , and$$
$$satisfy$$
$$1.295 \times {10}^{- 7} \leq exp ( - Δ H 2 \times 38.681731 ) \leq 3.406 \times {10}^{- 7}$$
$$when μ h 2 \geq μ h 1.$$

9. The organic EL element of claim 6, wherein
$$Δ H 1 , μ h 3 , and μ h 2$$
$$satisfy$$
$$4.367 \times {10}^{- 4} \leq \frac{μ h 3}{μ h 2} \times exp ( - Δ H 1 \times 38.681731 ) \leq 2.090 \times {10}^{- 2}$$
$$when μh 3 < μ h 2 , and$$
$$satisfy$$
$$4.367 \times {10}^{- 4} \leq exp ( - Δ H 1 \times 38.681731 ) \leq 2.090 \times {10}^{- 2}$$
$$when μ h 3 \geq μ h 2.$$

10. The organic EL element of claim 6, wherein
$$Δ E , μ e 1 , and μ e 2$$
$$satisfy$$
$$4.367 \times {10}^{- 4} \leq \frac{μ e 1}{μ e 2} \times exp ( - Δ E \times 38.681731 ) \leq 2.090 \times {10}^{- 2}$$
$$when μ e 1 < μ e 2 , and$$
$$satisfy$$
$$4.367 \times {10}^{- 4} \leq exp ( - Δ E \times 38.681731 ) \leq 2.090 \times {10}^{- 2}$$
$$when μ e 1 \geq μ e 2.$$

11. An organic electroluminescence (EL) element comprising:
an anode;
a hole transport layer above the anode, the hole transport layer containing a first organic semiconductor;
a light-emitting layer on the hole transport layer, the light-emitting layer containing a second organic semiconductor;
an electron transport layer on the light-emitting layer, the electron transport layer containing a third organic semiconductor; and
a cathode above the electron transport layer, wherein
the first organic semiconductor, the second organic semiconductor, and the third organic semiconductor each have a highest occupied molecular orbital (HOMO) and a lowest unoccupied molecular orbital (LUMO),
electron mobility and hole mobility of the second organic semiconductor are similar,
ΔE denoting a difference [eV] between a LUMO energy level of the first organic semiconductor and a LUMO energy level of the second organic semiconductor, μe1 denoting an electron mobility of the first organic semiconductor, and μe2 denoting an electron mobility of the second organic semiconductor
$$satisfy$$
$$\frac{μ e 1}{μ e 2} \times exp ( - Δ E \times 38.681731 ) \leq 2.090 \times {10}^{- 2}$$
$$when μ e 1 < μ e 2 , and$$
$$satisfy$$
$$exp ( - Δ E \times 38.681731 ) \leq 2.090 \times {10}^{- 2}$$
$$when μ e 1 \geq μ e 2 , and$$
ΔH denoting a difference [eV] between a HOMO energy level of the second organic semiconductor and a HOMO energy level of the third organic semiconductor, μh2 denoting a hole mobility of the second organic semiconductor, and μh3 denoting a hole mobility of the third organic semiconductor
$$satisfy$$
$$\frac{μ h 3}{μ h 2} \times exp ( - Δ H \times 38.681731 ) \leq 2.090 \times {10}^{- 2}$$
$$when μ h 3 < μ h 2 , and$$
$$satisfy$$
$$exp ( - Δ H \times 38.681731 ) \leq 2.090 \times {10}^{- 2}$$
$$when μ h 3 \geq μ h 2.$$

12. The organic EL element of claim 11, wherein
$$Δ E , μ e 1 , and μ e 2$$
$$satisfy$$
$$4.367 \times {10}^{- 4} \leq \frac{μ e 1}{μ e 2} \times exp ( - Δ E \times 38.681731 ) \leq 2.090 \times {10}^{- 2}$$
$$when μ e 1 < μ e 2 , and$$
$$satisfy$$
$$4.367 \times {10}^{- 4} \leq exp ( - Δ E \times 38.681731 ) \leq 2.090 \times {10}^{- 2}$$
$$when μ e 1 \geq μ e 2.$$

13. The organic EL element of claim 11, wherein
$$Δ H , μ h 3 , and μ h 2$$
$$satisfy$$
$$4.367 \times {10}^{- 4} \leq \frac{μ h 3}{μ h 2} \times exp ( - Δ H \times 38.681731 ) \leq 2.090 \times {10}^{- 2}$$
$$when μh 3 < μ h 2 , and$$
$$satisfy$$
$$4.367 \times {10}^{- 4} \leq exp ( - Δ H \times 38.681731 ) \leq 2.090 \times {10}^{- 2}$$
$$when μ h 3 \geq μ h 2.$$
